(19) United States
(12) Patent Application Publication
(10) Pub. No.: US 2026/0156909 A1
(43) Pub. Date: Jun. 4, 2026

(54) METHOD FOR MANUFACTURING SEMICONDUCTOR DEVICE AND PLASMA PROCESSING METHOD

(71) Applicant: Hitachi High-Tech Corporation, Minato-ku, Tokyo (JP)

(72) Inventors: Makoto MIURA, Tokyo (JP); Kiyohiko SATO, Tokyo (JP); Kohei KAWAMURA, Tokyo (JP); Satoshi SAKAI, Tokyo (JP)

(21) Appl. No.: 18/691,794

(22) PCT Filed: Mar. 13, 2023
(86) PCT No.: PCT/JP2023/009479

§ 371 Date: Mar. 13, 2024

(51) Int. Cl. H10D 84/01

(52) U.S. Cl. CPC H10D 84/0153; H10D 84/0158

(57) ABSTRACT

A plasma processing method in which a gate is cut by selectively etching a gate film stack including a gate oxide film, a work function metal, and a gate embedding metal with respect to a gate sidewall spacer and an interlayer insulating film of a source-drain region. A metal layer including a work function metal and a gate embedding metal is subjected to vertical etching along a gate cut mask, and then a protective insulating film is formed on a side wall of the metal layer. This is repeated a plurality of times using different protective film materials. A step of removing residues of the work function metal or the gate embedding metal is interposed between repetitions as necessary, and a gate insulating film exposed at the bottom of the cut region can be removed while the work function metal and the gate embedding metal.

### TECHNICAL FIELD

The present disclosure relates to a method for manufacturing a semiconductor device and a plasma processing method.

### BACKGROUND ART

In order to continuously improve functionality and performance of integrated circuit chips, high integration of transistors is ongoingly required. The high integration of transistors has been mainly achieved by miniaturization of transistor elements. Many improvements have been made to structures of transistors and materials constituting transistors so as to achieve miniaturization while maintaining or improving transistor performance. Examples of the above described improvements include introduction of strain into a source region and a drain region in a metal oxide semiconductor field effect transistor (MOSFET), introduction of a high dielectric gate insulating film and a metal, and change of a device structure from a planar type to a fin type having a three-dimensional structure. With further miniaturization, a gate all around (GAA) FET is expected in which a channel has a stacked body having a wire-like (fine-wire-like) shape or a sheet-like shape and the circumference of the channel is covered with a gate.

These improvements are introduced for the purpose of suppressing a short channel effect caused by a reduction in size of a transistor, that is, a phenomenon in which a leakage current flows between a source and a drain a distance between which is reduced even when the transistor is off. In other words, these are technological improvements that enable the miniaturization of transistors while preventing deterioration of transistor characteristics due to a short channel effect. However, if the miniaturization continues, a short channel effect will eventually become inevitable, and further miniaturization will be difficult.

In order to solve the above problem, a method for high integration of transistors that do not rely solely on the miniaturization of transistors is beginning to be applied. The most effective method is to reduce a distance between transistors. In integration in the related art, a distance between adjacent transistors is reduced at substantially the same ratio as a reduction in transistor size. However, higher integration can be achieved by further reducing a transistor spacing as compared to a reduction ratio of a transistor size. That is, even when a speed of the miniaturization of transistors is slowed down, a speed of the integration of transistors can be maintained by further reducing a spacing between transistors as compared with a miniaturization ratio of transistors. However, the above-described reduction in transistor spacing requires a change in layout rules that are determined by taking into account transistor characteristics, yield rate, and the like, and thus a process needs to be changed accordingly. The reduction in transistor spacing and the accompanying process change are called Design and Technology Co-Optimization (DTCO) and will become an increasingly important technology concept as the high integration of transistors progresses.

NPL 1 discloses a metal gate cutting technique which is one of DTCO techniques. In this technique, a high dielectric constant (high-k) gate insulating film, a work function metal, and a gate embedding metal are embedded in a gate region, and then a gate is cut by vertical etching. Conventionally, as a gate cutting process, a method of cutting a dummy gate made of polycrystalline silicon (poly-Si), filling a cut region with an insulating film, and removing the poly-Si dummy gate so as to embed a gate film stack (the gate insulating film, the work function metal, and the gate embedding metal) is applied. In the conventional method described above, since it is necessary to embed a gate film stack between a Fin channel of a Fin FET or a sheet-shaped channel of a GAA FET and an insulating film plug formed in a cut region, a spacing between the channel and the plug needs to be at least twice the total thickness of the gate film stack. In the above-described metal gate cutting technique, since a gate cutting process is performed after a gate film stack is formed, the above-described spacing between the channel and the plug can be reduced as compared to the conventional gate cutting process. That is, a distance between transistors via an insulating film plug can be reduced without reducing a transistor size.

NPL 1 discloses a specific example of the above-described metal gate cutting process. In a Fin FET process with a Fin channel, after a Fin channel, an element separation insulating film, a dummy gate, a gate sidewall spacer, a source and a drain, and an interlayer insulating film of a source-drain region are formed, the dummy gate is removed and replaced with a gate film stack, and the gate film stack is cut by dry etching using a gate cutting mask. At this time, the gate embedding metal, the work function metal, and the gate insulating film constituting the gate film stack are selectively etched with respect to an insulating film constituting the periphery of the gate, that is, the gate sidewall spacer and the interlayer insulating film of the source-drain region. By using selective etching conditions, only the gate can be etched even when the gate cut mask protrudes beyond the gate in a vertical direction of the gate. In other words, it is not necessary to match a width of the gate cut mask in a direction perpendicular to the gate with a length of the gate, that is, a gate wiring width, and thus it is possible to design a mask having a margin.

NPL 2 discloses a specific example in which etching for gate cutting is performed on a peripheral insulating film under non-selective conditions in the above-described metal gate cutting process. In vertically etching the gate film stack, the gate sidewall spacer exposed in a region not covered with the gate cut mask and the interlayer insulating film of the source-drain region are etched simultaneously with the gate film stack. By simultaneously etching the gate sidewall, the generation of residues of the gate film stack which are likely to remain at the gate sidewall can be suppressed.

### CITATION LIST

### Patent Literature

PTL 1: EP3836226

PTL 2: US2020/0135472B

### Non Patent Literature

NPL 1: A. Greene, et al., “Gate-Cut-Last in RMG to Enable Gate Extension Scaling and Parasitic Capacitance Reduction”, Proceedings of VLSI Symposium 2019, 2019, pp. T144 to T145

### SUMMARY OF INVENTION

### Technical Problem

When the metal gate cutting process disclosed in PTL 1 is applied, since vertical etching of the gate film stack is selectively performed with respect to the gate sidewall spacer and the interlayer insulating film of the source-drain region, processing a hole shape opening a region surrounded by a gate cut width and a gate length (gate wiring width) is required. This requires etching with a large aspect ratio, and the gate film stack is likely to remain at the bottom of the hole. In particular, a film deposited on a sidewall of the spacer is more difficult to remove at the bottom of the hole. When a metal film such as the work function metal or the gate embedding metal remains as etching residues along the sidewall of the spacer, there is a concern that cut gates may be electrically connected to each other at the bottom of a cut region, resulting in an electrical short circuit.

In the metal gate cutting process disclosed in PTL 2, since the gate sidewall spacer adjacent to the gate and the interlayer insulating film of the source-drain region are etched simultaneously with the gate film stack, a region etched at the time of gate cutting has a shape extending in a line shape in the vertical direction of the gate. An aspect ratio is reduced as compared to the processing of the hole shape described in PTL 1, making it easier to remove the gate film stack by etching. In particular, since the gate sidewall spacer is simultaneously etched, residues of the gate film stack on the spacer sidewall is eliminated, the gate film stack can be completely removed. This prevents electrical short circuit between cut gates. However, because the interlayer insulating film of the source-drain region is also etched simultaneously, when a distance between the channel and the cut region is shortened, an epitaxial growth layer formation layer constituting the source-drain is partially etched, and the surface area and the volume of the source-drain are reduced. As a result, when a metal contact layer is bonded to the source-drain, there is a concern that a contact resistance is reduced due to a reduction in a bonding area. In addition, since the above-described epitaxial growth layer often plays a role in applying strain to the source-drain to improve the mobility of a carrier propagating through the channel, the amount of the strain is reduced when the epitaxial growth layer is partially removed by etching, and there is a concern that transistor characteristics are degraded. Further, when the epitaxial growth layer is exposed during the process and a damage due to etching is applied to an exposed surface, there is a possibility that a defect occurs in the epitaxial growth layer in a subsequent process. Therefore, in order o to solve these concerns, a distance between the channel and the gate cut region needs to be increased to some extent. That is, in the metal gate cutting process disclosed in PTL 2, there is a concern that the reduction in the distance between the channel and the gate cut region, which leads to the high integration of transistors, may result in a trade-off relationship with transistor characteristics and process reproducibility.

The present disclosure provides a technique capable of, in a metal gate cutting process of selectively etching a gate film stack with respect to a gate sidewall spacer and an interlayer insulating film of a source-drain region, vertically etching a metal layer including a work function metal and a gate embedding metal, and then protecting a sidewall of the metal layer with a first insulating film, removing residues of the metal layer exposed at a lower portion of a cut region, protecting a sidewall of the cut region with a second insulating film, and removing a gate insulating film exposed at the bottom of the cut region. The disclosure further provides a technique that enables a series of these processes to be executed continuously by the same apparatus.

### Solution to Problem

Overview of representative embodiments of the disclosure will be briefly described below.

According to one embodiment of the disclosure, there is provided a technique (a method for manufacturing a semiconductor device or a plasma processing method) for a structure in which a metal layer is stacked on an insulating film, the technique including:
a first step of forming a cut region having a groove-like shape by etching the metal layer in a vertical direction;
a second step of depositing a protective insulating film on a sidewall of the cut region formed by the etching;
a third step of exposing a surface of the gate insulating film existing under the metal layer by anisotropically etching the protective insulating film in the vertical direction;
a fourth step of removing a part of the metal layer by isotropic etching;
a fifth step of forming a film stack of protective insulating films including the protective insulating film and a plurality of protective insulating films different from the protective insulating film on the sidewall of the cut region by repeating a cycle step including the second step and the third step a plurality of times using an insulating film material different from the protective insulating film with the fourth step interposed as necessary; and
a sixth step of removing a part of a gate insulating film exposed at a bottom of the cut region by etching.

### Advantageous Effects of Invention

According to the one embodiment of the present disclosure, in a metal gate cutting process, it is possible to prevent the gate film stack from remaining on the spacer sidewall while maintaining conditions for selectively etching the gate film stack with respect to the gate sidewall spacer and the interlayer insulating film of the source-drain region. That is, it is possible to shorten a distance between a Fin channel of a Fin FET or a sheet-like channel of a GAA FET and a gate cut region, and to simultaneously insulation isolation between cut gates. Further, an increase in the number of process steps can be suppressed by apparatus characteristics by which a plurality of steps for performing the metal gate cutting process can be performed as a continuous process by the same apparatus.

Other problems and novel features will become apparent from the description of the present specification and the accompanying drawings.

### BRIEF DESCRIPTION OF DRAWINGS

FIG. 1 is a bird's-eye view of a manufacturing step of a metal gate cutting process in an FET of an embodiment 1.

FIG. 2 is a plan view illustrating a manufacturing step of the metal gate cutting process in the FET of the embodiment 1.

FIG. 3A is a cross-sectional view of a gate region of a transistor in a direction parallel to a gate, illustrating a manufacturing step of the metal gate cutting process in the FET of the embodiment 1.

FIG. 3B is a cross-sectional view of a gate cut region in a direction perpendicular to the gate, illustrating a manufacturing step of the metal gate cutting process in the FET of the embodiment 1.

FIG. 4A is a cross-sectional view of the gate region of the transistor in a direction parallel to the gate, illustrating a manufacturing step of the metal gate cutting process in the FET of the embodiment 1.

FIG. 4B is a cross-sectional view of the gate cut region in a direction perpendicular to the gate, illustrating a manufacturing step of the metal gate cutting process in the FET of embodiment 1.

FIG. 5A is a cross-sectional view of the gate region of the transistor in a direction parallel to the gate, illustrating a manufacturing step of the metal gate cutting process in the FET of the embodiment 1.

FIG. 5B is a cross-sectional view of a gate cut in a direction perpendicular to the gate, illustrating a manufacturing step of the metal gate cutting process in the FET of the embodiment 1.

FIG. 6A is a cross-sectional view of the gate region of the transistor in a direction parallel to the gate, illustrating a manufacturing step of the metal gate cutting process in the FET of the embodiment 1.

FIG. 6B is a cross-sectional view of a gate cut region in a direction perpendicular to the gate, illustrating a manufacturing step of the metal gate cutting process in the FET of the embodiment 1.

FIG. 7A is a cross-sectional view of the gate region of the transistor in a direction parallel to the gate, illustrating a manufacturing step of the metal gate cutting process in the FET of the embodiment 1.

FIG. 7B is a cross-sectional view of a gate cut region in a direction perpendicular to the gate, illustrating a manufacturing step of the metal gate cutting process in the FET of the embodiment 1.

FIG. 8A is a cross-sectional view of the gate region of the transistor in a direction parallel to illustrating a manufacturing step of the metal gate cutting process in the FET of embodiment 1.

FIG. 8B is a cross-sectional view of a gate cut region in a direction perpendicular to the gate, illustrating a manufacturing step of the metal gate cutting process in the FET of the embodiment 1.

FIG. 9A is a cross-sectional view of the gate region of the transistor in a direction parallel to the gate, illustrating a manufacturing step of the metal gate cutting process in the FET of embodiment 1.

FIG. 9B is a cross-sectional view of a gate cut region in a direction perpendicular to the gate, illustrating a manufacturing step of the metal gate cutting process in the FET of the embodiment 1.

FIG. 10A is a cross-sectional view of the gate region of the transistor in a direction parallel to the gate, illustrating a manufacturing step of the metal gate cutting process in the FET of the embodiment 1.

FIG. 10B is a cross-sectional view of the gate cut region in a direction perpendicular to the gate, illustrating a manufacturing step of the metal gate cutting process in the FET of the embodiment 1.

FIG. 11A is a cross-sectional view of the gate region of the transistor in a direction parallel to the gate, illustrating a manufacturing step of the metal gate cutting process in the FET of the embodiment 1.

FIG. 11B is a cross-sectional view of the gate cut region in a direction perpendicular to the gate, illustrating a manufacturing step of the metal gate cutting process in the FET of the embodiment 1.

FIG. 12 is a flowchart of manufacturing steps of the metal gate cutting process in the FET of the embodiment 1.

FIG. 13A is a cross-sectional view of the gate region of the transistor in a direction parallel to the gate, illustrating a step of removing a gate insulating film of the metal gate cutting process in the FET of the embodiment 1.

FIG. 13B is a cross-sectional view of the gate cut region of the transistor in a direction perpendicular to the gate, illustrating the step of removing the gate insulating film of the metal gate cutting process in the FET of the embodiment 1.

FIG. 14A is a cross-sectional view of the gate region of the transistor in a direction parallel to the gate, illustrating a step of removing a gate insulating film of the metal gate cutting process in the FET of the embodiment 1.

FIG. 14B is a cross-sectional view of the gate cut region of the transistor in a direction perpendicular to the gate, illustrating the step of removing the gate insulating film of the metal gate cutting process in the FET of the embodiment 1.

FIG. 15A is a cross-sectional view of the gate region of the transistor in a direction parallel to the gate, illustrating a step of removing a gate insulating film of the metal gate cutting process in the FET of the embodiment 1.

FIG. 15B is a cross-sectional view of the gate cut region of the transistor in a direction perpendicular to the gate, illustrating the step of removing the gate insulating film of the metal gate cutting process in the FET of the embodiment 1.

FIG. 16 is a diagram illustrating a configuration example of a plasma processing apparatus.

FIG. 17A is a cross-sectional view of a gate region of a transistor in a direction parallel to a gate, illustrating a step of removing a gate insulating film of a metal gate cutting process in an FET of an embodiment 2.

FIG. 17B is a cross-sectional view of a gate cut region of the transistor in a direction perpendicular to the gate, illustrating the step of removing the gate insulating film of the metal gate cutting process in the FET of the embodiment 2.

FIG. 18A is a cross-sectional view of a gate region of a transistor in a direction parallel to a gate, illustrating a step of removing a gate insulating film of a metal gate cutting process in an FET of the embodiment 2.

FIG. 18B is a cross-sectional view of the gate cut region of the transistor in a direction perpendicular to the gate, illustrating the step of removing the gate insulating film of the metal gate cutting process in the FET of the embodiment 2.

FIG. 19A is a cross-sectional view of the gate region of the transistor in a direction parallel to the gate, illustrating a step of removing the gate insulating film of the metal gate cutting process in the FET of the embodiment 2.

FIG. 19B is a cross-sectional view of the gate cut region of the transistor in a direction perpendicular to the gate, illustrating the step of removing the gate insulating film of the metal gate cutting process in the FET of the embodiment 2.

FIG. 20 is a flowchart of manufacturing steps of the metal gate cutting process in the FET of the embodiment 2.

FIG. 21A is a cross-sectional view of a gate region of a transistor in a direction parallel to a gate, illustrating a step of removing a gate insulating film of a metal gate cutting process in an FET of an embodiment 3.

FIG. 21B is a cross-sectional view of a gate cut region of the transistor in a direction perpendicular to the gate, illustrating the step of removing the gate insulating film of the metal gate cutting process in the FET of embodiment 3.

FIG. 22A is a cross-sectional view of the gate region of the transistor in a direction parallel to the gate, illustrating the step of removing the gate insulating film of the metal gate cutting process in the FET of the embodiment 3.

FIG. 22B is a cross-sectional view of the gate cut region of the transistor in a direction perpendicular to the gate, illustrating the step of removing the gate insulating film of the metal gate cutting process in the FET of the embodiment 3.

FIG. 23A is a cross-sectional view of a gate region of a transistor in a direction parallel to a gate, illustrating a step of removing a gate insulating film of a metal gate cutting process in an FET of an embodiment 4.

FIG. 23B is a cross-sectional view of a gate cut region of the transistor in a direction perpendicular to the gate, illustrating the step of removing the gate insulating film of the metal gate cutting process in the FET of the embodiment 4.

FIG. 24A is a cross-sectional view of the gate region of the transistor in a direction parallel to the gate, illustrating the step of removing the gate insulating film of the metal gate cutting process in the FET of the embodiment 4.

FIG. 24B is a cross-sectional view of the gate cut region of the transistor in a direction perpendicular to the gate, illustrating the step of removing the gate insulating film of the metal gate cutting process in the FET of the embodiment 4.

FIG. 25A is a cross-sectional view of the gate region of the transistor in a direction parallel to the gate, illustrating the step of removing the gate insulating film of the metal gate cutting process in the FET of the embodiment 4.

FIG. 25B is a cross-sectional view of the gate cut region of the transistor in a direction perpendicular to the gate, illustrating the step of removing the gate insulating film of the metal gate cutting process in the FET of the embodiment 4.

FIG. 26 is a flowchart of manufacturing steps of the metal gate cutting process in the FET of the embodiment 4.

### DESCRIPTION OF EMBODIMENTS

Embodiments of the disclosure will be described below in accordance with the accompanying drawings. It should be noted that the disclosure is not limited to the embodiments described below, and various modifications can be made within the scope of the technical idea. In all the drawings for describing the embodiments, members having the same functions are denoted by the same reference signs, and the repetitive descriptions thereof may be omitted. In addition, it goes without saying that many changes can be made to the contents disclosed in the present embodiment, such as changing a combination of materials or manufacturing steps. In addition, the drawings are not necessarily scaled in an exact manner, and important parts are schematically drawn in an emphasized manner so as to clarify the logics. In addition, in order to further clarify the description, the drawings may be schematically illustrated as compared to an actual aspect, but the drawings are merely examples and do not limit the interpretation of the present disclosure.

### Embodiment 1

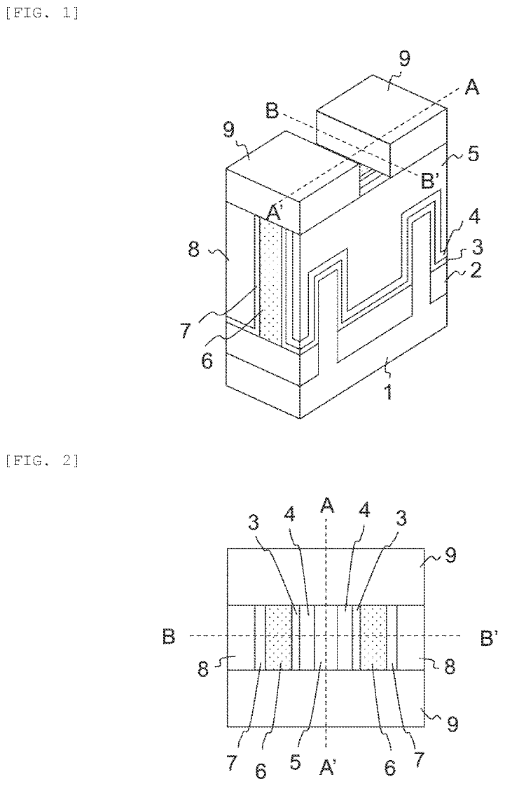

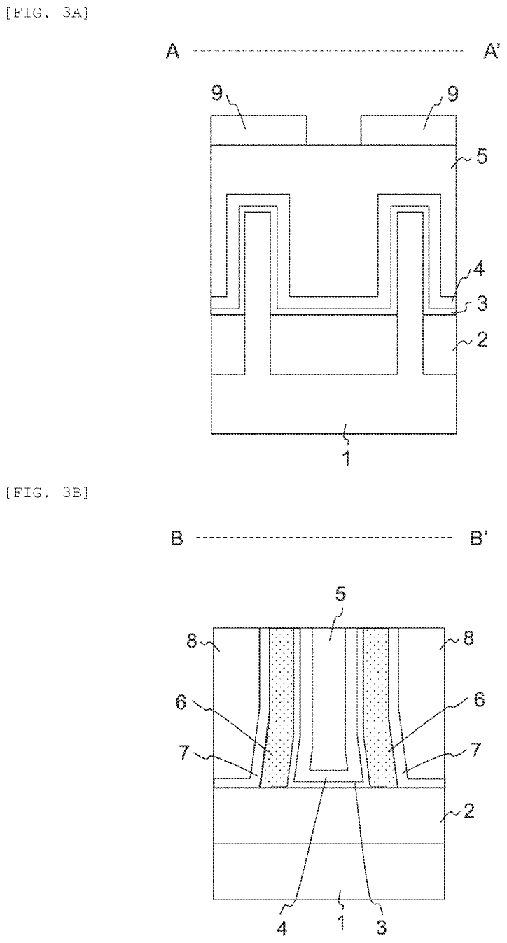

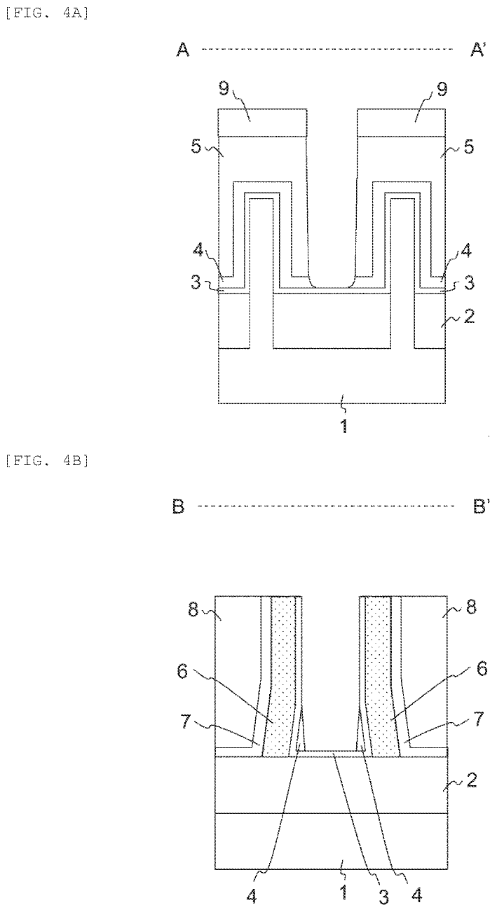

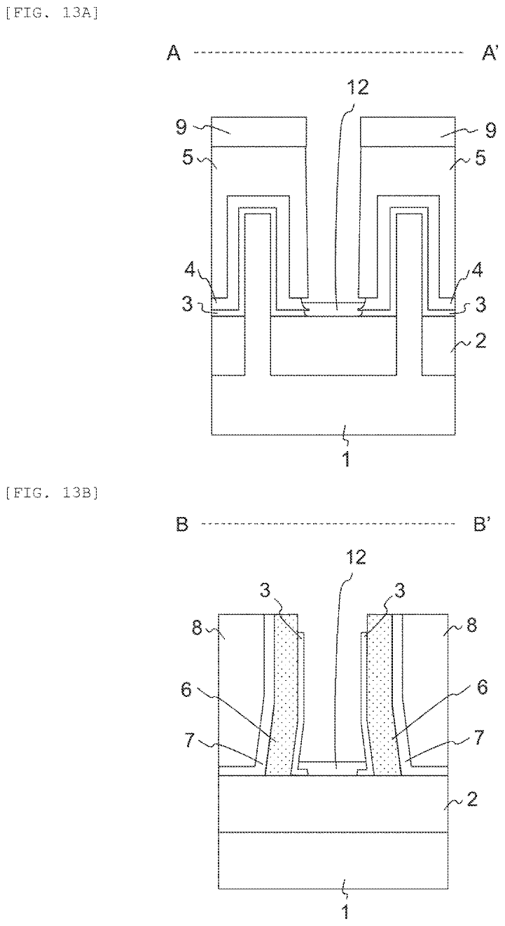

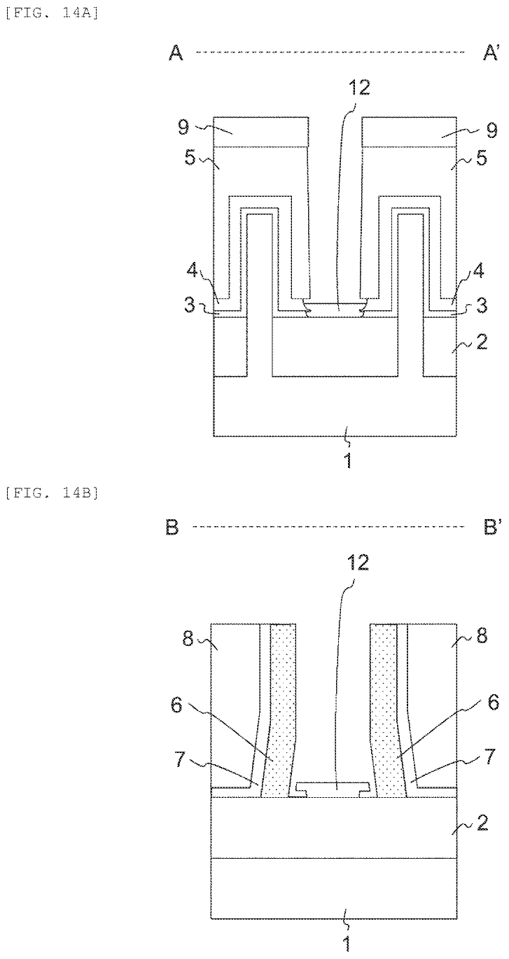

In an embodiment 1, in a manufacturing process (a method for manufacturing method of a semiconductor device or a plasma processing method) for a Fin type field effect transistor (Fin-type FET) or a gate all around type field effect transistor (GAA-type FET) as a semiconductor device, a metal gate cutting process and a process step in the above-described process that can remove metal residues in a cut region while selectively etching a gate film stack including a metal with respect to a peripheral film by stacking a plurality of sidewall protective films made of different materials will be described in detail. First, the above-described process will be described using FIG. 1, FIG. 2, FIG. 3A to FIG. 11A, FIG. 3B to FIG. 11B, FIG. 12, FIG. 13A to FIG. 15A, and FIG. 13B to FIG. 15B. The method for manufacturing a semiconductor device or the plasma processing method described in the present embodiment is a method for forming a Fin-type FET or a GAA-type FET in which a gate formation region includes a Fin-like channel or a fine-wire-like or sheet-like channel stacked in a direction perpendicular to a substrate, a gate is cut between the channels, and the cut region is insulated and isolated by an insulating film.

FIG. 1 and FIG. 2 are a bird's-eye view and a plan view of a structure immediately before the above-described metal gate cutting process in the manufacturing process of a Fin-type FET or a GAA-type FET, respectively. FIG. 3A to FIG. 11A are cross-sectional views of a gate region of a transistor in a direction parallel to a gate (taken along lines A-A′ in FIG. 1 and FIG. 2), illustrating a series of steps excluding a step of removing a gate insulating film remaining on a gate sidewall spacer in the metal gate cutting process. FIG. 3B to FIG. 11B are cross-sectional views of a gate cut region in a direction perpendicular to the gate (taken along lines B-B′ in FIG. 1 and FIG. 2), illustrating the series of steps excluding the step of removing the gate insulating film remaining on the gate sidewall spacer in the metal gate cutting process. FIG. 12 shows a flowchart of a series of manufacturing steps illustrated in FIG. 3A to FIG. 11A and FIG. 3B to FIG, 11B. FIG. 13A to FIG. 15A are cross-sectional views of the gate region of the transistor in a direction parallel to the gate (taken along the lines A-A′ in FIG. 1 and FIG. 2), illustrating the step of removing the gate insulating film remaining on the gate sidewall spacer after the metal gate cutting process shown in FIG. 12. FIG. 13B to FIG. 15B are cross-sectional views of the gate cut region in a direction perpendicular to the gate (taken along the lines B-B′ in FIG. 1 and FIG. 2), illustrating the step of removing the gate insulating film remaining on the gate sidewall spacer after the metal gate cutting process shown in FIG. 12.

In FIG. 1, a single-crystal semiconductor substrate 1 has a fin-type channel structure including a channel formed of a periodic pattern or an equivalent linear pattern. A shallow trench isolation (STI) insulating film (referred to as an STI insulating film) 2 constituting an element isolation region is formed on the semiconductor substrate 1. Here, the height of the STI insulating film 2 is set such that the Fin-type channel is partially exposed. In a gate region oriented in a direction perpendicular to the Fin-type channel, a gate insulating film 3, a work function metal 4, and a gate embedding metal 5 are sequentially stacked on the Fin-type channel exposed above the STI insulating film 2. A gate sidewall spacer 6 is formed at a sidewall of the gate region, and an etching stopper layer 7 and an interlayer insulating film 8 of a source-drain region are deposited on a region surrounded by the STI insulating film 2 and the gate sidewall spacer 6. A hard mask 9 in which a gate cut region is patterned is formed on a gate film stack including the gate insulating film 3, the work function metal 4, and the gate embedding metal 5, and the gate sidewall spacer 6, the etching stopper layer 7, and the interlayer insulating film 8 of the source-drain region. In other words, a gate structure includes the gate film stack, and has a shape oriented in a direction perpendicular to the orientation direction of the Fin-type channel. Here, a channel structure can be formed so as to include a fin-like, wire-like, or sheet-like channel on the semiconductor substrate.

As the semiconductor substrate 1, for example, silicon (Si) may be used, or a substrate in which silicon germanium (SiGe) is deposited on Si may be used, or a silicon-on-insulator (SOI) substrate in which a film stack of an insulating film such as a silicon oxide film (SiO₂) and an Si layer is used on an Si substrate may be used. As a process for forming the Fin-type channel, a method of etching a substrate in a vertical direction after patterning using a lithography technique is used. For example, in the case where a laser using an argon fluoride gas (ArF) as a light source is used for the patterning, self-aligned double patterning (SADP) can be used when a pattern period is, for example, 40 nm or more and 80 nm or less. Alternatively, self-aligned quadruple patterning (SAQP) can be used when the pattern period is, for example, 20 nm or more and 40 nm or less. In the case of performing extreme ultraviolet (EUV) exposure of a wavelength of 13.5 nm, single exposure (single patterning) can be used when the pattern period is, for example, 40 nm or more. SADP can be used when the pattern period is, for example, 20 nm or more and 40 nm or less. In the case of a Fin-type FET, one transistor includes one or a plurality of Fin-type channels, but the two Fin-type channels illustrated in FIG. 1 are Fin-type channels belonging to different transistors. In this case, a spacing between the two fin-type channels illustrated in FIG. 1 is designed to be wider than a minimum spacing of the pattern, and is formed by removing one or a plurality of fins by etching after forming the pattern structure.

The STI insulating film 2 is formed, for example, by forming an insulating film such as an SiO₂ film, a silicon oxynitride film (SiON), or a silicon carbon xide film (SiCO) by chemical vapor deposition (CVD) or the like and etching back the insulating film 2 until the Fin-type channel is partially exposed.

The gate sidewall spacer 6 is formed on a sidewall of a dummy gate (not illustrated). The dummy gate is formed by depositing a dummy gate insulating film made of an SiCO₂ or equivalent insulating film and amorphous Si or polycrystalline Si on the Fin-type channel and the STI insulating film 2, and applying a periodic pattern equivalent line pattern oriented in a direction perpendicular to the Fin-type channel. For the patterning, a single exposure using the ArF light source or the SADP method is used in accordance with a pattern period. The size of a gate pattern may be set, for example, such that a gate pitch is in a range from 40 nm to 70 nm and a width of the dummy gate, that is, a gate length is in a range from 10 nm to 30 nm. The gate sidewall spacer 6 is obtained by forming an SiON film or a silicon carbon oxynitride film (SiOCN), which is a low dielectric constant film, or an SiCO film or the like on the dummy gate using the CVD method or the like and performing etchback. The film thickness of the gate sidewall spacer 6 may be adjusted to be in a range from 5 nm to 15 nm, for example.

The etching stopper layer 7 and the interlayer insulating film 8 of the source-drain region are formed by forming a source-drain of a transistor (not illustrated) after forming the gate sidewall spacer 6, and being stacked sequentially on a region surrounded by the gate sidewall spacer 6 and the STI insulating film 2. The etching stopper layer 7 can be obtained by forming a silicon nitride film (SiN), or a silicon carbon nitride film (SiCN), or an SiOCN or SiON film using the CVD method or the like. The film thickness of the etching stopper layer 7 may be adjusted to be in a range from 2 nm to 10 nm, for example. The interlayer insulating film 8 is formed so as to fill the source-drain region surrounded by the gate sidewall spacers 6 outside the gate region, where an SiO₂ film, or an SiON film, or an SiOCN film, or the like may be used as a material, and the CVD method or the like may be used as a film forming method.

The gate film stack including the gate insulating film 3, the work function metal 4, and the gate embedding metal 5 is formed on the Fin-type channel after the dummy gate and the dummy gate insulating film are removed. The dummy gate is removed by exposing the dummy gate using chemical mechanical polishing (CMP) after formation of the interlayer insulating film 8 of the source-drain region, and sequentially removing the dummy gate and the dummy gate insulating film by etching. The gate film stack is formed by, for example, the CVD or an atomic layer deposition (ALD) method. For the gate insulating film 3, for example, a high dielectric material such as hafnium oxide (HfO₂) or aluminum oxide (Al₂O₃), or a film stack of the high dielectric material may be used. The film thickness of the gate insulating film 3 may be adjusted to be in a range from 1 nm to 3 nm, for example. The work function metal 4 is determined in consideration of target transistor performance or a conductive type of the transistor. For example, a titanium nitride film (TiN) or a tantalum nitride film (TaN), or a metal compound having an equivalent work function may be used for the work function metal 4 that determines a threshold voltage of a p-type FET. For example, titanium aluminum (TiAl), or a metal in which carbon (C), oxygen (O), nitrogen (N), or the like is added to TiAl, or a metal compound having an equivalent work function may be used for the work function metal 4 that determines a threshold voltage of an n-type FET. The work function metal 4 may be made of a single film or a plurality of film stacks, and the total film thickness is adjusted to be in a range from 2 nm to 10 nm, for example. The gate embedding metal 5 is deposited for the purpose of reducing a metal resistance in the gate, and a material such as tungsten (W) may be used.

After the gate film stack is formed, a surface is flattened by the CMP using the work function metal 4 or the gate embedding metal 5 as a stopper, and the hard mask 9 is deposited. A resist (not illustrated) is deposited on the hard mask 9, patterning in which the gate cut region is opened via the resist is performed, and the resist is removed, thereby obtaining the structure of FIG. 1. Here, the resist may be a three-layer resist made of a spin-on carbon film, a spin-on glass film, and an organic resist. The spin-on carbon film is an organic film mainly containing carbon, and the spin-on glass films is an organic film containing Si and oxygen. Usually, in the processing using the three-layer resist, it is often the case that after the spin-on glass film is etched using the resist and the spin-on carbon film is etched using the spin-on glass film as a mask, the resist and the spin-on glass film are removed and the spin-on carbon film is used as a mask. In this case, the hard mask 9 is mainly made of the spin-on carbon film. The hard mask 9 may be an insulating film such as an SiO₂ film or a silicon nitride film (Si₃N₄). In that case, the three-layer resist is deposited on the hard mask 9, and then patterning is performed, and the hard mask is etched to remove the three-layer resist, thereby obtaining the structure of FIG. 1. A gate cut pattern is oriented in a direction perpendicular to the gate, and after the patterning, surfaces of the gate sidewall spacer 6, the etching stopper layer 7, and the interlayer insulating film 8 may be exposed simultaneously with the gate film stack. In addition, a gate cut width may be set to be in a range from 10 nm to 30 nm, for example.

It should be noted that FIG. 1 illustrates a configuration example in which a Fin-type FET is used, but a GAA-type FET may be used. In that case, the channel has a structure in which wire-like or sheet-like semiconductor layers are stacked. The above-described stacked channel structure may be formed, for example, by forming a Fin shape using a film stack in which an Si layer and an SiGe layer are alternately and repeatedly formed, removing the dummy gate and the dummy gate insulating film, and then selectively removing the SiGe layer with respect to the Si layer by etching.

FIG. 2 illustrates a plan view which is the bird's-eye view illustrated in FIG. 1 as viewed from above. In the gate region sandwiched between different gate sidewall spacers 6, the gate insulating films 3, the work function metals 4, and the gate embedding metal 5 are sequentially formed from sidewalls of the gate sidewall spacers 6 so as to fill the gate, and the etching stopper layers 7 and the interlayer insulating films 8 of the source-drain region are formed outside the gate sidewall spacers 6. In the region opened by the hard mask 9, the gate sidewall spacers 6, the gate insulating films 3, the work function metals 4, the gate embedding metal 5, the etching stopper layers 7, and the interlayer insulating films 8 may be exposed.

FIG. 3A and FIG. 3B are respectively a cross-sectional view of the gate region of the transistor in a direction parallel to the gate (taken along the lines A-A′ in FIG. 1 and FIG. 2) and a cross-sectional view of the gate cut region in a direction perpendicular to the gate (taken along the lines B-B′ in FIG. 1 and FIG. 2) in the structure illustrated in FIG. 1 and FIG. 2. As illustrated in FIG. 3B, the gate region surrounded by the gate sidewall spacers 6 has a shape which is flared in the vicinity of a bottom surface. This is because a dummy gate pattern serving as a base in forming the gate sidewall spacers 6, is likely to have a tapered shape with a flared bottom at the processing using dry etching.

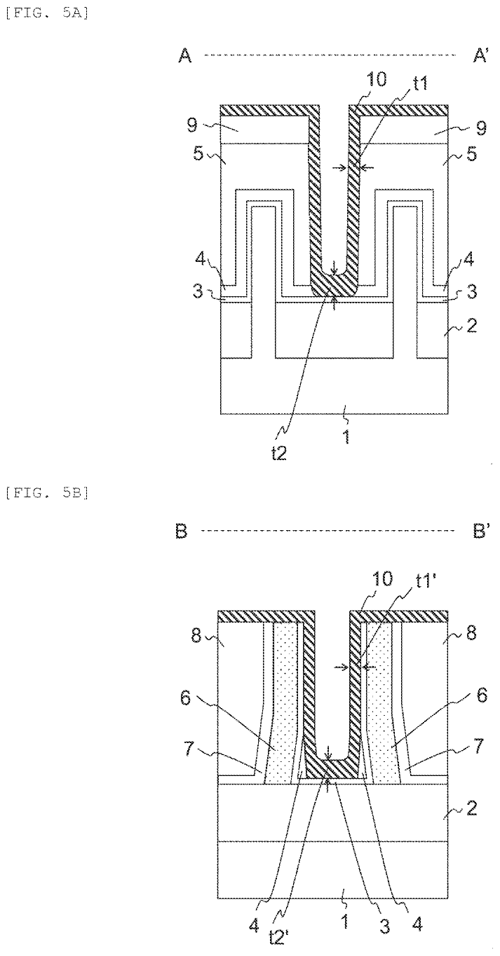

The structure illustrated in FIG. 4A and FIG. 4B is obtained from the structure illustrated in FIG. 3A and FIG. 3B by anisotropically etching the gate embedding metal 5 and the work function metals 4 along the gate cut pattern opened by the hard mask 9. For the anisotropic etching of the gate embedding metal 5 and the work function metal 4, for example, a halogen-based gas such as tetrafluoromethane (CF₄), trifluoromethane (CHF₃), boron trichloride (BCl₃), chloride (Cl₂), or hydrogen chloride (HCl), or a mixed gas thereof, or a mixed gas obtained by mixing any of these gases with a gas such as oxygen (O₂) and nitrogen (N₂), or argon (Ar) and helium (He), or methane (CH₄) may be used. The etching is performed under such conditions that the hard mask 9, the gate sidewall spacer 6, the etching stopper layer 7, and the interlayer insulating film 8 of the source-drain region are selectively etched. For example, in selectively etching the gate embedding metal 5, when the gate embedding metal 5 made of a material mainly containing W, a mixed gas of CHF₃ and O₂ or an equivalent gas may be used. In selectively etching the work function metal 4, for example, when the work function metal 4 is TiN or TaN, a mixed gas of CF₄ and O₂, a mixed gas of Cl₂ and Ar, or a mixed gas of Cl₂, O₂, and He, or the like may be used. For example, when the work function metal 4 is made of TiAl or a material in which C, O, N, or the like is added to TiAl, for example, a mixed gas of CF₄ and Cl₂, a mixed gas of CF₄ and HCl, or a mixed gas obtained by mixing any of these gases with a gas such as Ar, He, or N₂ may be used as an etching gas. The anisotropic etching of the gate embedding metal 5 and the work function metal 4, that is, the present step illustrated in FIG. 4A and FIG. 4B is equivalent to gate metal vertical etching 101 in the process flowchart of FIG. 12. The gate metal vertical etching 101 is performed under etching conditions in which the gate insulating film 3 is used as a stopper. Thus, as illustrated in FIG. 4A, the upper surface of the gate insulating film 3 is exposed at the bottom of the gate cut region after the etching. In addition, as illustrated in FIG. 4B, since the gate sidewall spacer 6 has a tapered shape which is flared in the vicinity of a bottom portion, the work function metal 4 and the gate embedding metal 5 are likely to remain at the tapered portion.

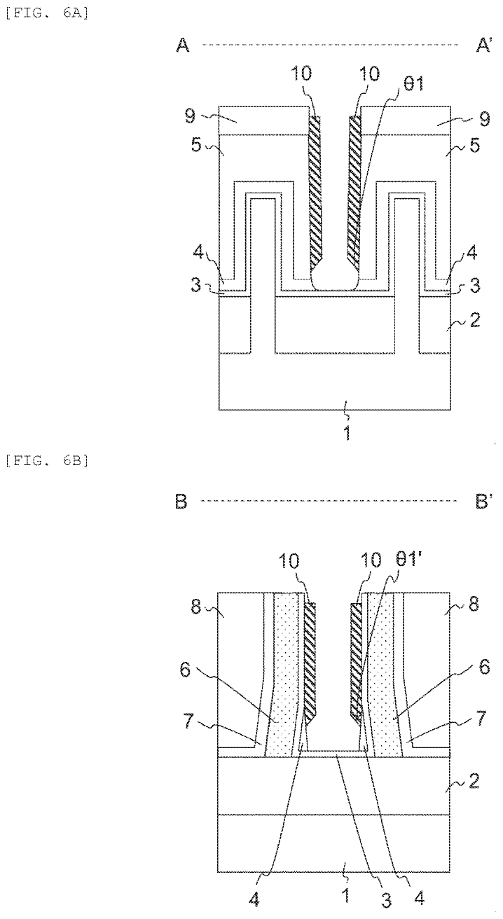

In FIG. 5A and FIG. 5B, a first protective insulating film 10 is deposited by a film forming technique using the atomic layer deposition (ALD) method. The protective insulating film 10 is deposited on the upper surface and a sidewall of the hard mask 9, the upper surface and a sidewall of the gate insulating film 3, a sidewall of the gate embedding metal 5, a sidewall of the work function metal 4, the upper surface of the gate sidewall spacer 6, the upper surface of the etching stopper layer 7, and the upper surface of the interlayer insulating film 8 of the source-drain region. The material of the protective insulating film 10 is preferably an insulating film containing nitrogen in consideration of the etching selectivity with respect to the hard mask 9, the gate insulating film 3, the gate sidewall spacer 6, the etching stopper layer 7, the interlayer insulating film 8, and the like, and may be, for example, an Si₃N₄ film or an equivalent SiON film. The film thickness of the protective insulating film 10 is adjusted to be about 2 nm to 3 nm, for example. The ALD method has the advantage that a thin film can be deposited with good controllability even for a complex shape with many irregularities. When the protective insulating film 10 is an Si₃N₄ film formed by the ALD method, for example, bis (tertbutylamino) silane (BTBAS), bis (diethylamino) silane (BDEAS), or dichlorosilane (SiH₂Cl₂) is used as a raw material of Si, and a gas containing nitrogen such as an N₂ gas, a mixed gas of an N₂ gas and an H₂ gas, or an ammonia (NH₃) gas is used as a raw material of nitrogen. It should be noted that the protective insulating film 10 may be made of a nitrogen-free film such as SiO₂, or may be formed by the CVD method or the like. The height of the gate including the work function metal 4 and the gate embedding metal 5 illustrated in FIG. 5A in a direction perpendicular to the substrate is designed to be in a range from about 50 nm to 200 nm. Although a gate cut width is about 10 nm to 30 nm, since the gate cut width is reduced along with the high integration of transistors, an etching pattern is expected to have a pattern width of about 10 nm and a depth of about 200 nm. When the protective insulating film 10 is formed to have such a narrow and deep pattern, the film thicknesses in the vertical direction at the bottom of a groove (t2 in FIG. 5A and t2′ in FIG. 5B) are expected to be thicker than the film thicknesses in the horizontal direction at a sidewall (t1 in FIG. 5A, and t1′ in FIG. 5B). When the film thickness t1 or t1′ of the protective insulating film 10 in the horizontal direction at a sidewall of the pattern is, for example, 2 nm to 3 nm, the film thickness t2 or t2′ in the vertical direction at the bottom of the groove is expected to be, for example, 3 nm to 6 nm. The present step illustrated in FIG. 5A and FIG. 5B is equivalent to first protective insulating film deposition 102 in the process flowchart of FIG. 12, and may be performed continuously in the same apparatus chamber following the gate metal vertical etching 101 illustrated in FIG. 4A and FIG. 4B.

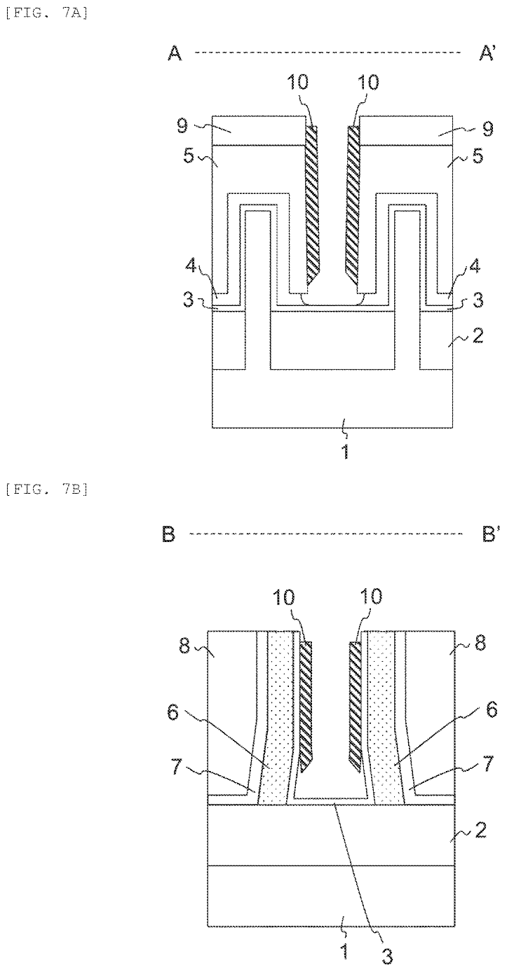

In the step illustrated in FIG. 6A and FIG. 6B, the protective insulating film 10 is etched in the vertical direction. The etching is performed under selective etching conditions with respect to the hard mask 9, the gate insulating film 3, the gate sidewall spacer 6, the etching stopper layer 7, and the interlayer insulating film 8. For example, when the protective insulating film 10 is an Si₃N₄ film, a gas obtained by adding Cl₂ or the like to a mixed gas of O₂ and a halogen-based gas such as CF₄ or octafluorocyclobutane (C₄F₈), or an equivalent gas may be used as an etching gas. By this etching, the upper surface of the gate insulating film 3 is exposed at the bottom of the gate cut region. In this etching, an etching time is determined in consideration of the film thickness of the protective insulating film 10 in the vertical direction at the bottom of the groove such that the upper surface of the gate insulating film 3 is exposed and the upper end of the protective insulating film 10 in contact with the gate sidewall spacer 6 is located between the upper end and the lower end of the hard mask 9 after the etching. The film thickness of the protective insulating film 10 in the vertical direction at the bottom of the groove is thicker than the film thickness of the protective insulating film 10 in the horizontal direction at a sidewall of the groove. Thus, at the bottom of the groove after the etching, the protective insulating film 10 at the sidewall is also partially removed by the etching, the work function metal 4 and the gate embedding metal 5 are partially exposed at a sidewall of the cut gate (FIG. 6A), and the work function metal 4 is partially exposed at the sidewall of the gate sidewall spacer 6 (FIG. 6B). At this time, a lower portion of the protective insulating film 10 has an eaves structure as illustrated in FIG. 6A and FIG. 6B, and an angle θ1 formed by the sidewall of the cut gate (FIG. 6A) and the eaves and an angle θ1′ formed by the sidewall of the gate sidewall spacer 6 (FIG. 6B) and the eaves are both acute angles of 90° or less. The present step illustrated in FIG. 6A and FIG. 6B is equivalent to first protective insulating film vertical etching 103 in the process flowchart of FIG. 12, and may be performed continuously in the same apparatus chamber following the first protective insulating film deposition 102 illustrated in FIG. 5A and FIG. 5B.

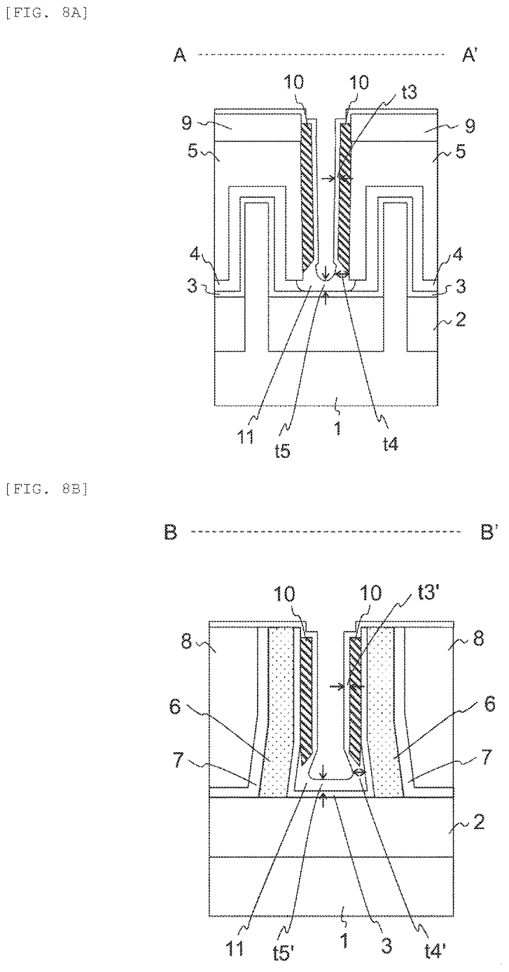

Following the above-described step, the work function metal 4 is partially removed using isotropic etching so as to obtain the structure illustrated in FIG. 7A and FIG. 7B. The etching is performed under such conditions that the protective insulating film 10, the gate insulating film 3, the gate embedding metal 5, the hard mask 9, the gate sidewall spacer 6, the etching stopper layer 7, and the interlayer insulating film 8 are selectively etched and the work function metal 4 is isotropically etched. For example, when the work function metal 4 is TiN or TaN, a mixed gas of Cl₂, O₂, and He, or a mixed gas of Cl₂ and Ar, or a mixed gas of CF₄ and O₂, or the like may be used. When the work function metal 4 is made of TiAl or a material in which C, O, N, or the like is added to TiAl, for example, a mixed gas of CF₄ and Cl₂, a mixed gas of CF₄ and HCl, or a mixed gas obtained by mixing any of these gases with a gas such as Ar, He, or N₂ may be used as an etching gas. By this etching, the work function metal 4 remaining on the gate sidewall spacer 6 via the gate insulating film 3 is removed (FIG. 7B). An etching amount in this step is adjusted to be 1 to 2 times the film thickness of the work function metal 4, and an etching time is controlled such that the work function metal 4 on the channel is not removed. Although FIG. 7A and FIG. 7B illustrate a case in which only the work function metal 4 is removed, when the gate embedding metal 5 remains on the sidewall of the gate sidewall spacer 6 in addition to the work function metal 4 in FIG. 6B, the remaining gate embedding metal 5 is also removed in this step. The present step illustrated in FIG. 7A and FIG. 7B is equivalent to work function control metal film isotropy etching 104 in the process flowchart of FIG. 12, and may be performed continuously in the same apparatus chamber following the first protective insulating film vertical etching 103 illustrated in FIG. 6A and FIG. 6B.

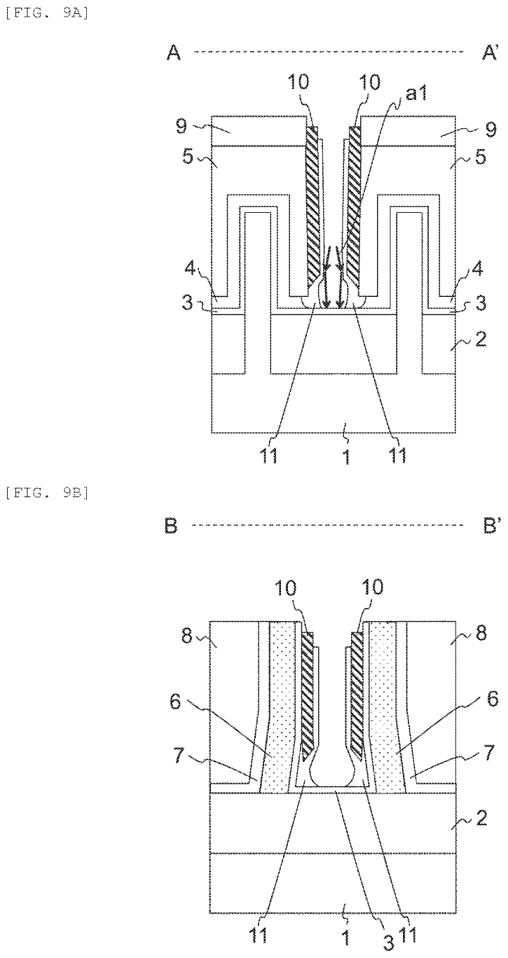

In FIG. 8A and FIG. 8B, a second protective insulating film 11 is deposited on the first protective insulating film 10 using the ALD method. By this step, a film stack of protective insulating films including the first protective insulating film 10 and the second protective insulating film 11 is formed. In the film stack of the protective insulating films, the lower layer side is the first protective insulating film 10 and the upper layer side is the second protective insulating film 11. The insulating film material of the second protective insulating film 11 is different from the insulating film material of the first protective insulating film 10. The second protective insulating film 11 is deposited on a sidewall and the upper surface of the first protective insulating film 10, the upper surface and a sidewall of the hard mask 9, the upper surface and a sidewall of the gate insulating film 3, a sidewall of the gate embedding metal 5, a sidewall of the work function metal 4, the upper surface of the gate sidewall spacer 6, the upper surface of the etching stopper layer 7, and the upper surface of the interlayer insulating film 8 of the source-drain region. As compared to the film thickness t1 or t1′ of the first protective insulating film 10 in the horizontal direction, the film thicknesses (t3 in FIG. 8A and t3′ in FIG. 8B) of the second protective insulating film 11 in the horizontal direction may be set to be equal (t3=t1, t3′=t1′) or thinner (t3<t1, t3′<t1′). When the film thicknesses t1 and t1′ are, for example, 2 nm to 3 nm, the film thicknesses t3 and t3′ are preferably, for example, 1 nm to 3 nm. The second protective insulating film 11 is also deposited on the eaves formed at the lower portion of the first protective insulating film 10, and on sidewalls of the work function metal 4 and the gate embedding metal 5 (FIG. 8A) and a sidewall of the gate insulating film 3 (FIG. 8B) in a region under the first protective insulating film 10 exposed by the step illustrated in FIG. 7A and FIG. 7B. Since the second protective insulating film 11 is isotropically deposited, at a portion under the eaves of the first protective insulating film 10, the film formed in the vertical direction under the eaves overlaps the film formed in the horizontal direction from the sidewalls of the work function metal 4 and the gate embedding metal 5 (FIG. 8A) or from the sidewall of the gate insulating film 3 (FIG. 8B), and thus the film thicknesses (t4 in FIG. 8A and t4′ in FIG. 8B) of the second protective insulating film 11 in the horizontal direction are thicker than the film thicknesses (t3 in FIG. 8A and t3′ in FIG. 8B) of the second protective insulating film 11 on the sidewall of the first protective insulating film 10. However, it is formed thinner than the sum of the film thickness t3 (or t3′) and the film thickness t1 (or t1′) (t3<t4<t3+t1, t3′<t4<t3′+t1′). In addition, since the film thicknesses t3 and t3′ are set to be thinner than the film thicknesses t1 and t1′, the film thicknesses (t5 in FIG. 8A and t5′ in FIG. 8B) in the vertical direction of the second protective insulating film 11 on the gate insulating film 3 are equal to the sum of the film thickness t3 (or t3′) and the film thickness t1 (or t1′) (t3+t1=t5, t3′+t1′=t5′), or smaller than the sum of the film thickness t3 (or t3′) and the film thickness t1 (or t1′) (t3+t1>t5, t3′+t1′>t5′). As the second protective insulating film 11, a film that can be isotropically formed with good controllability even for a complex shape with finer irregularities is used. The second protective insulating film 11 is, for example, an aluminum oxide (Al₂O₃) film or an equivalent aluminum oxynitride (ALON) film. When an Al₂O₃ film is formed, for example, trimethylaluminum (TMA) (Al(CH₃)₃) may be used as a raw material of aluminum (Al) and vaporized water (H₂O) may be used as a raw material of oxygen. Since a precursor made of Al(CH₃)₃ has high reactivity with hydroxyl groups (OH groups) formed on a surface by the supply of H₂O, an Al₂O₃ film can be formed with a good coverage even on a surface with irregularities. Thus, the Al₂O₃ film is also isotropically formed inside the pattern including a narrow opening illustrated in FIG. 8A and FIG. 8B. It should be noted that the second protective insulating film 11 may be made of an Al-free film such as an oxide film or a nitride film, or may be formed by the CVD method or the like. The present step illustrated in FIG. 8A and FIG. 8B is equivalent to second protective insulating film deposition 105 in the process flowchart of FIG. 12, and may be performed continuously in the same apparatus chamber following the work function control metal film isotropy etching 104 illustrated in FIG. 7A and FIG. 7B.

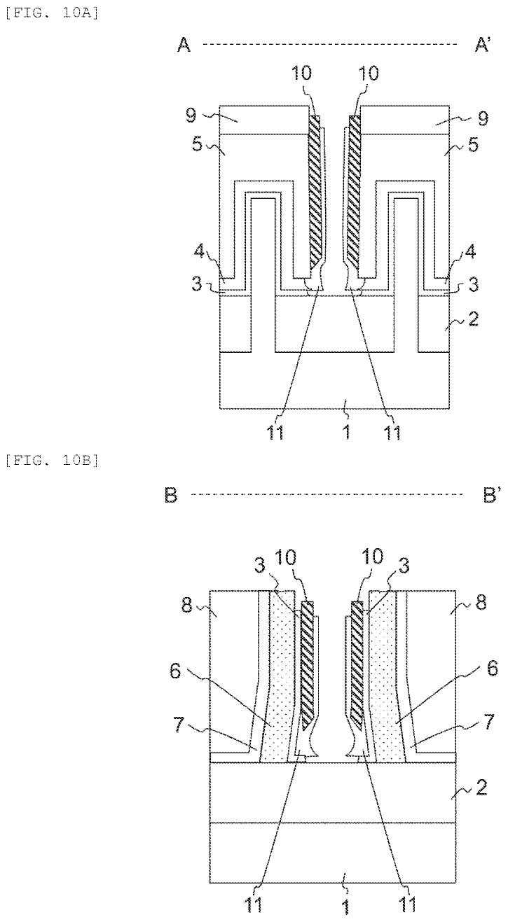

Next, in the step illustrated in FIG. 9A and FIG. 9B, the second protective insulating film 11 is etched in the vertical direction. The etching is performed under selective etching conditions with respect to the first protective insulating film 10, the hard mask 9, the gate insulating film 3, the gate sidewall spacer 6, the etching stopper layer 7, and the interlayer insulating film 8. For example, when the second protective insulating film 11 is an Al₂O₃ film, BCl₃, a mixed gas of BCl₃ and Cl₂, a mixed gas obtained by mixing any of these gases with argon Ar, N₂, or O₂, or an equivalent gas may be used. By this etching, the upper surface of the gate insulating film 3 is exposed. As illustrated in FIG. 8A, in the structure before this etching is performed, the film thickness of the second protective insulating film 11 in the horizontal direction at the portion under the eaves formed by the first protective insulating film 10 is formed to be thinner than the sum of the thicknesses of the first protective insulating film 10 and the second protective insulating film 11 in the horizontal direction at a portion above the eaves (t4<t3+t1). Thus, in this etching step, at the portion under the eaves, the sidewall of the second protective insulating film 11 is almost protected by the eaves formed by the first protective insulating film 10. Even when ions generated from the etching gas are incident on the substrate 1 in a direction oblique to the vertical direction, the ions are almost reflected by the sidewall of the first protective insulating film 10 to change the angle (a1 in FIG. 9A). Therefore, the etching gas ions do not reach the sidewall of the second protective insulating film 11 at the portion under the eaves, and the second protective insulating film 11 is not etched at the portion under the eaves. By the process described above, the upper portion of the gate insulating film 3 can be opened while the work function metal 4 and the gate embedding metal 5 at the sidewall of the cut region are protected. The present step illustrated in FIG. 9A and FIG. 9B is equivalent to second protective insulating film vertical etching 106 in the process flowchart of FIG. 12, and may be performed continuously in the same apparatus chamber following the second protective insulating film deposition 105 illustrated in FIG. 8A and FIG. 8B. It should be noted that cycle processes illustrated in steps 102-103 and 105-106 of FIG. 12 (gas and film formation conditions may be changed) are not limited to two cycles, and can be further repeated a plurality of times. That is, when a combination of film forming steps (102, 105) and etching steps (103, 106) is regarded as one cycle process, in FIG. 12, the combination of the film forming processes and the etching processes is performed for two cycles (step 102 and step 103 constitutes a first cycle process and step 105 and step 106 constitute a second cycle process), and step 104 of removing the work function metal 4 is interposed between the first cycle process and the second cycle process. The gas and film formation conditions may be changed between the first cycle process (step 102 and step 103) and the second cycle process (step 105 and step 106). In addition, the number of cycle processes is not limited to two cycles, but may be repeated a plurality of times to be a plurality of cycles. In that case, step 104 of removing the work function metal 4 is performed once or a plurality of times, but is not necessarily performed every time between the cycle processes.

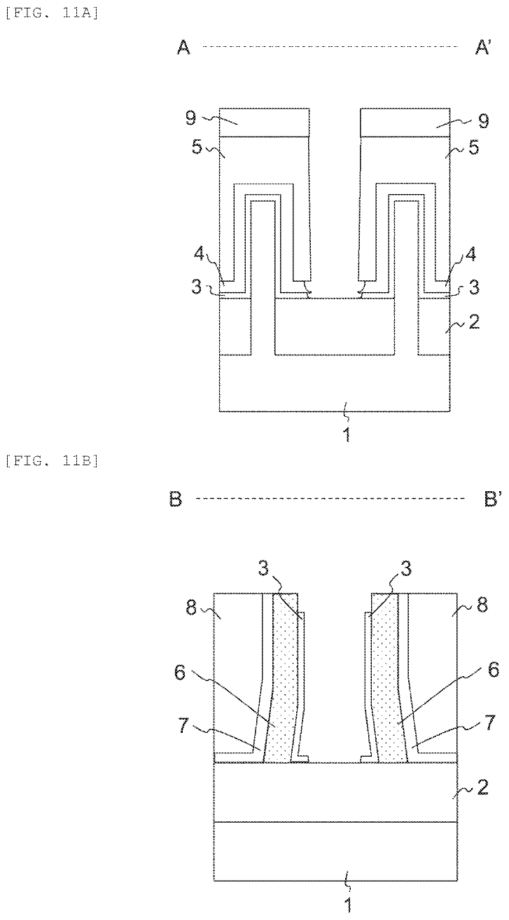

In the step illustrated in FIG. 10A and FIG. 10B, the gate insulating film 3 is isotropically etched. The etching is performed under selective etching conditions with respect to the second protective insulating film 11, the first protective insulating film 10, the hard mask 9, the STI insulating film 2, the gate sidewall spacer 6, the etching stopper layer 7, and the interlayer insulating film 8. In performing the etching, since the sidewalls of work function metal 4 and the gate embedding metal 5 are covered with the first protective insulating film 10 and the second protective insulating film 11, it is not necessary to consider the etching selectivity for these metals (4 and 5). As an etching gas, for example, CF₄, a mixed gas of Cl₂, hydrogen bromide (HBr), and O₂, or an equivalent gas may be used. An etching amount in this step is adjusted to be 1 to 2 times the film thickness of the gate insulating film 3, and an etching time is controlled such that the gate insulating film 3 on the channel is not removed. The present step illustrated in FIG. 10A and FIG. 10B is equivalent to gate insulating film isotropic etching 107 in the process flowchart of FIG. 12, and may be performed continuously in the same apparatus chamber following the second protective insulating film vertical etching 106 illustrated in FIG. 9A and FIG. 9B.

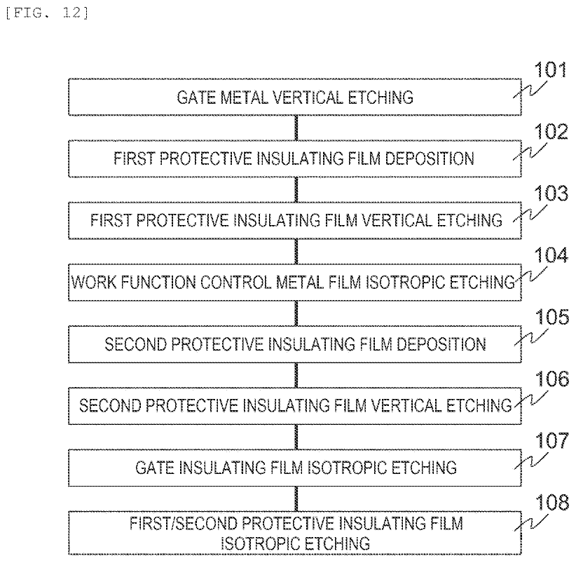

In the step illustrated in FIG. 11A and FIG. 11B, the second protective insulating film 11 and the first protective insulating film 10 are removed in sequence by isotropic etching. The etching of the second protective insulating film 11 is performed under selective etching conditions with respect to the first protective insulating film 10, the hard mask 9, the gate insulating film 3, the work function metal 4, the gate embedding metal 5, the STI insulating film 2, the gate sidewall spacer 6, the etching stopper layer 7, and the interlayer insulating film 8. For example, when the second protective insulating film 11 is an Al₂O₃ film, a mixed of O₂, BCl₃, and Ar, or an equivalent gas may be used as an etching gas. This etching is performed under such conditions that the second protective insulating film 11 is etched for a time 1 to 2 times the etching time required for etching the film thickness, and the second protective insulating film 11 is almost completely removed. Following the second protective insulating film 11, the first protective insulating film 10 is removed by isotropic etching. This etching is performed under selective etching conditions with respect to the hard mask 9, the gate insulating film 3, the work function metal 4, the gate embedding metal 5, the STI insulating film 2, the gate sidewall spacer 6, the etching stopper layer 7, and the interlayer insulating film 8. For example, when the protective insulating film 10 is an Si₃N₄ film, a gas such as CHF₃, or difluoromethane (CH₂F₂), or fluoromethane (CH₃F) may be used, or a mixed gas of H₂ and a fluorocarbon-based gas such as CF₄ or C₄F₈, or an equivalent gas may be used as an etching gas. Similar to the etching of the second protective insulating film 11, this etching is performed under such conditions that the first protective insulating film 10 is etched for a time 1 to 2 times the etching time required for etching the film thickness, and the first protective insulating film 10 is almost completely removed. By this step, a sidewall of the work function metal 4, a sidewall of the gate embedding metal 5 (FIG. 11A), and a sidewall of the gate insulating film 3 on the gate sidewall spacer 6 (FIG. 11B) are exposed. The sidewalls of the work function metal 4 and the gate embedding metal 5 exposed in this step (FIG. 11A) have, at lower portion thereof, a curved shape in which an opening width of the cut pattern of the work function metal 4 and the gate insulating film 3 is wider than an opening width of the cut pattern covered with the gate embedding metal 5. This shape contributes to good embeddability and good isotropic film deposition in forming a plug structure by embedding an insulating film in the cut region in a subsequent step, and thus a film density of the insulating film for forming the plug is kept constant at the bottom of the cut region. This produces an effect of suppressing the generation of voids in the plug due to reduction in film density. The present step illustrated in FIG. 11A and FIG. 11B is equivalent to first/second protective insulating film isotropic etching 108 in the process flowchart of FIG. 12, and may be performed continuously in the same apparatus chamber following the gate insulating film isotropic etching 107 illustrated in FIG. 10A and FIG. 10B. That is, the gate metal vertical etching 101 (FIG. 4A, FIG. 4B) to the first/second protective insulating film isotropic etching 108 (FIG. 11A, FIG. 11B) of FIG. 12 can be continuously performed in the Same apparatus chamber.

By performing the process including these continuous steps, in the metal gate cutting step using selective etching in the Fin-type FET or the GAA-type FET, the gate can be cut without generating metal residues of the work function metal 4, the gate embedding metal 5, or the like on the sidewall of the gate sidewall spacer 6 in the gate cut region, and a distance between the plug for insulating and isolating the gates and the channel of the FET can be shortened.

In consideration of the insulating properties and process stability of the insulating film plug formed in the gate cut region, the gate insulating film 3 remaining on the sidewall of the gate sidewall spacer 6 in the gate cut region may be removed before the insulating film plug is formed. In that case, following the step illustrated in FIG. 11A and FIG. 11B, the gate insulating film 3 may be removed by isotropic etching continuously in the sane apparatus, or the gate insulating film 3 remaining on the sidewall of the gate sidewall spacer 6 may be removed while the gate insulating film 3 opened at a lower portion of the gate cut region is protected by the steps illustrated in FIG. 13A to FIG. 15A and FIG. 13B to FIG. 15B.

In the steps of removing the gate insulating film 3 remaining on the sidewall of the gate sidewall spacer 6 while protecting the gate insulating film 3 opened at the lower portion of the gate cut region, a groove formed by the gate cut region is first filled with a coating film such as a spin-on carbon film which is an organic film, and then the carbon film is etched in the vertical direction to a certain amount, thereby obtaining the structure illustrated in FIG. 13A and FIG. 13B. Here, the etching amount of a carbon film 12 is adjusted such that the upper end of the carbon film 12 after the etching is located at a position higher than a boundary position between the work function metal 4 and the gate insulating film 3 at the sidewall of the gate cut region, and is located at a position at which a part of the gate insulating film 3 remaining on the sidewall of the gate sidewall spacer 6 is exposed. The gate insulating film 3 remaining on the sidewall of the gate sidewall spacer 6 is preferably exposed to as deep position as possible in the gate cut region. Thus, when the film thickness of the gate insulating film 3 is 1 nm to 3 nm, the height of the carbon film 12 remaining on the STI insulating film 2 after the etching of the carbon film 12 may be adjusted to about 3 nm to 10 nm. By this step, the gate insulating film 3 remaining under the work function metal 4 (FIG. 13A) is protected by the carbon film 12.

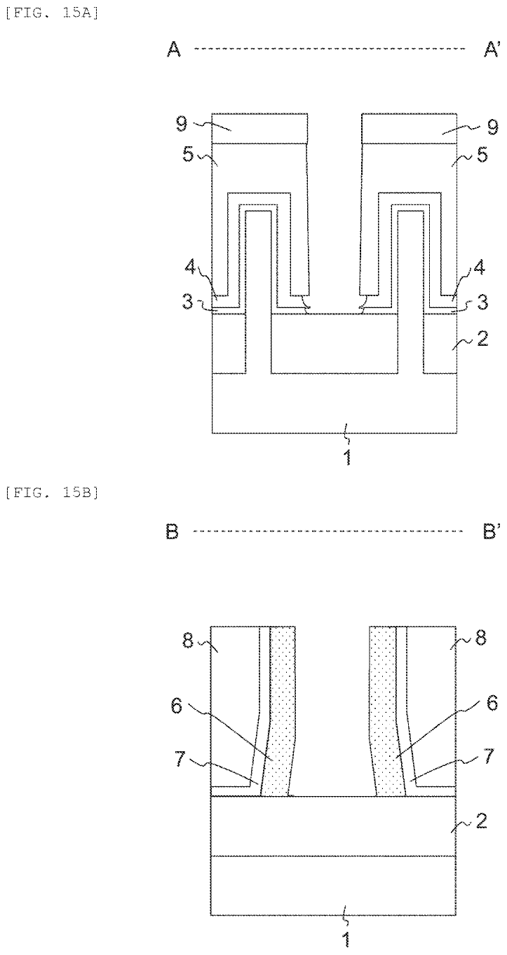

In the step illustrated in FIG. 14A and FIG. 14B, the gate insulating film 3 is isotropically etched so as to remove the gate insulating film 3 remaining on the sidewall of the gate sidewall spacer 6 (FIG. 14B). This etching is performed under selective etching conditions with respect to the hard mask 9, the STI insulating film 2, the work function metal 4, the gate embedding metal 5, the gate sidewall spacer 6, the etching stopper layer 7, and the interlayer insulating film 8. Wet etching or dry etching may be used for this etching. In the case of performing wet etching, for example, when the gate insulating film 3 is HfO₂, a solution such as hydrofluoric acid (HF) is used. In the case of performing dry etching, for example, a mixed gas of Cl₂, HBr, and O₂, or an equivalent gas is used as an etching gas. An etching amount in this step is adjusted to be 1 to 5 times the film thickness of the gate insulating film 3, and an etching time is controlled such that the gate insulating film 3 on the channel is not removed.

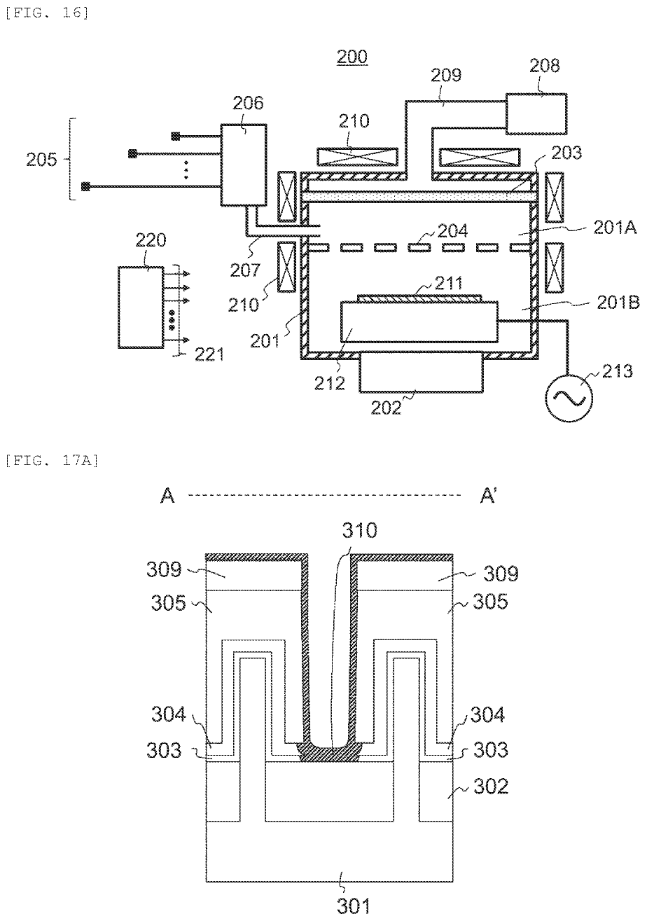

Next, in the step illustrated in FIG. 15A and FIG. 15B, the carbon film 12 is removed by ashing, for example, in an oxygen plasma atmosphere. The step of vertically etching the carbon film 12 illustrated in FIG. 13A and FIG. 13B to the step of removing the carbon film 12 illustrated in FIG. 15A and FIG. 15B may be continuously performed in the same apparatus chamber. The apparatus used at this time may be the same as the apparatus in which the gate metal vertical etching 101 (FIG. 4A, FIG. 4B) to the first/second protective insulating film isotropic etching 108 (FIG. 11A, FIG. 11B) of FIG. 12 are performed.

By using a plasma processing apparatus equipped with an ALD film forming function and an anisotropic isotropic etching control function, an integrated process from the gate metal vertical etching 101 (FIG. 4A, FIG. 4B) to the first/second protective insulating film isotropic etching 108 (FIG. 11A, FIG. 11B) of FIG. 12 and an integrated process from the vertical etching of the carbon film 12 (FIG. 13A, FIG. 13B) to the removal of the carbon film 12 by etching (FIG. 15A, FIG. 15B) can be continuously performed in the same plasma processing apparatus. The plasma processing apparatus may be any of an etching apparatus using inductively coupled plasma (ICP), an etching apparatus using capacitively coupled plasma (CCP), and an etching apparatus using electron cyclotron resonance (ECR) plasma.

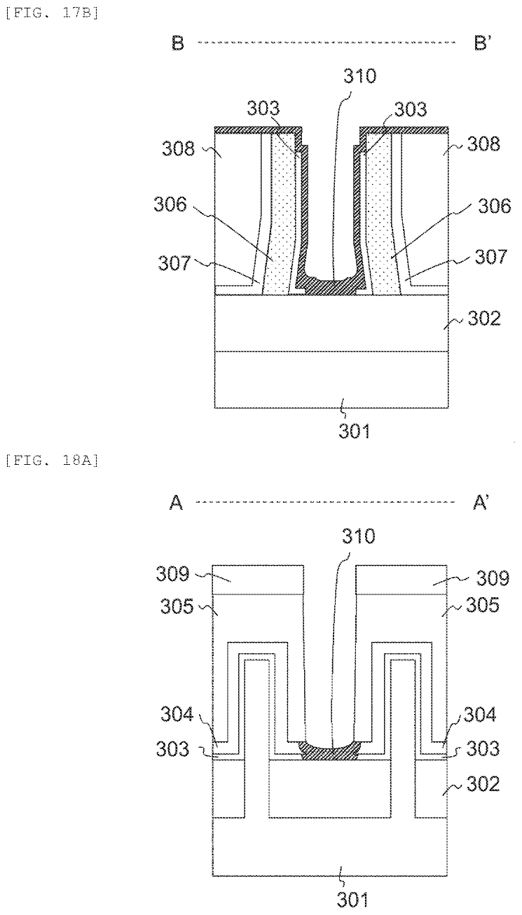

As an example, FIG. 16 illustrates a configuration of a plasma processing apparatus 200 using microwave ECR plasma. The plasma processing apparatus 200 includes a processing chamber 201, the processing chamber 201 is connected to a vacuum exhaust apparatus (not illustrated) via a vacuum exhaust port 202, and the interior of the processing chamber 201 is kept at a vacuum of about 0.1 Pa to 10 Pa during plasma processing. In the processing chamber 201, a window portion 203 having a function of transmitting microwaves and a function of airtightly sealing the processing chamber 201 and a porous plate 204 for shielding ions are arranged. The processing chamber 201 is divided into an upper portion 201A of the processing chamber 201 and a lower portion 201B of the processing chamber 201 by the porous plate 204. The material of the window portion 203 is made of a material that transmits microwaves and, for example, a dielectric material such as quartz is used. The porous plate 204 has a plurality pores, and the material of the porous plate 204 may be made of, for example, a dielectric material such as quartz or alumina.

A gas supply mechanism includes a gas source 205, a gas supply apparatus 206, and a gas introduction port 207, and supplies a raw material gas for plasma processing. The gas source 205 has a plurality of types of gases necessary for treatment. The gas supply apparatus 206 includes a control valve that controls supply and shutdown of a gas and a mass flow controller that controls a gas flow rate. The gas introduction port 207 is provided between the window portion 203 and the porous plate 204.

A waveguide 209 that transmits electromagnetic waves is connected to the upper portion of the processing chamber 201, and a plasma generation radio frequency power source 208, which is a radio frequency power source, is connected to an end of the waveguide 209. The plasma generation radio frequency power source 208 is a power source for generating electromagnetic waves for plasma generation and uses microwaves with a frequency of 2.45 GHZ as the electromagnetic waves. Microwaves generated from the plasma generation radio frequency power source 208 propagate through the waveguide 209 to be incident inside the processing chamber 201. The waveguide 209 includes a vertical waveguide extending in the vertical direction and a waveguide converter serving as a corner for deflecting the direction of the microwaves by 90 degrees, whereby the microwaves are vertically incident in the processing chamber 201. The microwaves propagate vertically inside the processing chamber 201 via the window portion 203. A magnetic field generation coil 210 arranged at the outer circumference of the processing chamber 201 forms a magnetic field in the processing chamber 201. The microwaves emitted from the plasma generation radio frequency power source 208 generate high-density plasma inside the processing chamber 201 by interaction with the magnetic field formed by the magnetic field generation coil 210.

At the bottom of the processing chamber 201, a specimen table 212 is arranged facing the window portion 203. For example, aluminum or titanium is used as a material of the specimen table 212. A semiconductor substrate 211, which is a specimen, is placed on the upper surface of the specimen table 212 and held by the specimen table 212. Here, the central axes of the waveguide 209, the processing chamber 201, the specimen table 212, and the semiconductor substrate 211 coincide with each other. In addition, an electrode for electrostatically chucking the semiconductor substrate 211 is provided inside the specimen table 212, and the semiconductor substrate 211 is electrostatically chucked to the specimen table 212 when a DC voltage is applied. Further, a radio frequency voltage is applied to the specimen table 212 from a high-frequency bias power supply controlling isotropy and anisotropy of etching. The frequency of applied radio frequency bias may be, for example, 400 kHz.

Each mechanism of the plasma processing apparatus 200 is controlled by a control signal 221 from a control unit 220. The control unit 220 uses the control signal 221 to instruct each mechanism to execute a predetermined operation in accordance with treatment conditions (anisotropic etching, isotropic etching, ALD film formation, etc.) performed by the plasma processing apparatus 200, thereby controlling each mechanism. The control unit 220 controls the plasma generation radio frequency power source 208 so as to control on and off of electromagnetic waves for plasma generation. In addition, the control unit 220 controls the gas supply mechanism so as to adjust the type and the flow rate of a gas to be introduced into the processing chamber 201. The control unit 220 also controls the high-frequency bias power supply 213 so as to control the intensity of a radio frequency voltage to be applied to the semiconductor substrate 211 on the specimen table 212.

When anisotropic etching is performed using the plasma processing apparatus 200, the control unit 220 controls the magnetic field generation coil 210 such that plasma is generated in the lower portion 201B of the processing chamber 201 under the porous plate 204. Since the porous plate 204 is made of a dielectric material, microwaves pass through the porous plate 204 and interact with the magnetic field at the lower portion 201B of the processing chamber 201 to generate plasma. Further, a radio frequency bias is applied to the specimen table 212 on which an Si substrate 1 is placed as the semiconductor substrate 211. As a result, ions in the plasma are attracted to the Si substrate 1 without being blocked by the porous plate 204 or the like, enabling anisotropic etching while maintaining verticality.

When isotropic etching is performed using the plasma processing apparatus 200, the control unit 220 controls the magnetic field generation coil 210 such that a plasma generation position is the upper portion 201A of the processing chamber 201 above the porous plate 204. Since ions in the plasma generated in the upper portion 201A of the processing chamber 201 are blocked by the porous plate 204, only radicals in the plasma are supplied to the lower portion 201B of the processing chamber 201. This enables isotropic etching using the radicals.

When film forming is performed by the ALD method using the plasma processing apparatus 200, the following cycle process under the control of the control unit 220 may be applied. For example, when an Si₃N₄ film is formed by the ALD method, BTBAS or BDEAS, each of which is a raw material of Si, or SiH₂Cl₂, which is a gaseous gas, is used. When BTBAS or BDEAS, each of which is a liquid raw material, is used, the liquid raw material is vaporized and fed to a gas line as a gaseous gas. The gaseous gas which is a raw material and Ar which is a carrier gas are fed to the processing chamber 201 and absorbed to a substrate surface as precursor of Si. Then, a purge gas such as an Ar gas is used to exhaust unnecessary precursor inside the processing chamber 201. Next, a gas containing nitrogen such as an N₂ gas, a mixed gas of an N₂ gas and an H₂ gas, or an NH₃ gas, is introduced into the processing chamber 201 to be converted into plasma and reacted on the substrate surface. Then, an inert gas such as Ar is introduced into the processing chamber 201 again so as to purge the processing chamber 201, whereby unnecessary gases in the processing chamber 201 are exhausted. By this series of processes, an Si₃N₄ film having a film thickness of atomic layer level in principle is deposited on the substrate surface. By repeatedly performing this series of processes (execution of the cycle process), a thin insulating film is formed by the ALD method. For example, when an Al₂O₃ film is formed by the ALD method, the Al₂O₃ film may be formed by using Al(CH₃)₃ as a precursor of Al and vaporized H₂O as a raw material of oxygen, and performing a cycle process similar to the cycle process of the above-described Si₃N₄.

### Embodiment 2

An embodiment 2 provides a technique in which, in the metal gate cutting process of the embodiment 1, the series of steps of cutting a metal gate shown in the flowchart of FIG. 12 to the steps of removing the gate insulating film 3 remaining on the gate sidewall spacer 6 illustrated in FIG. 13A and FIG. 13B to FIG. 15A and FIG. 15B are continuously performed in the same apparatus chamber

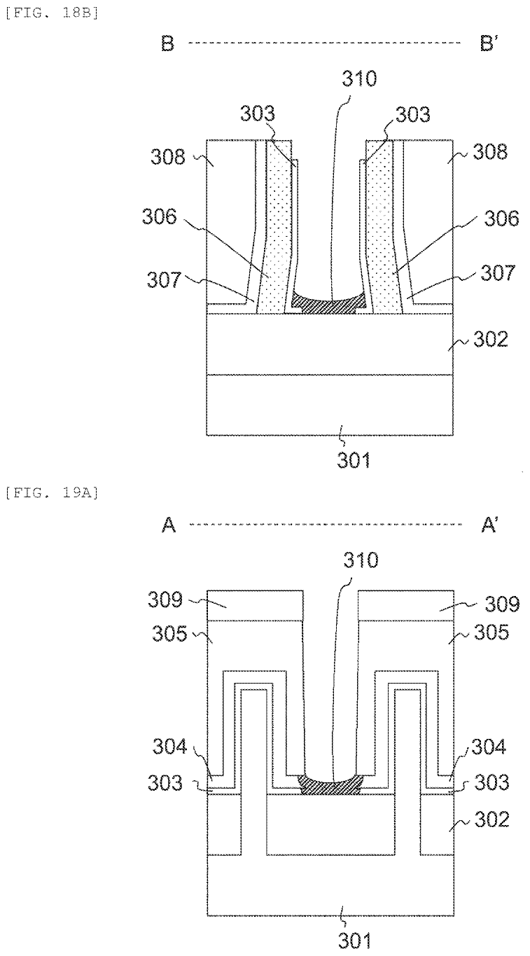

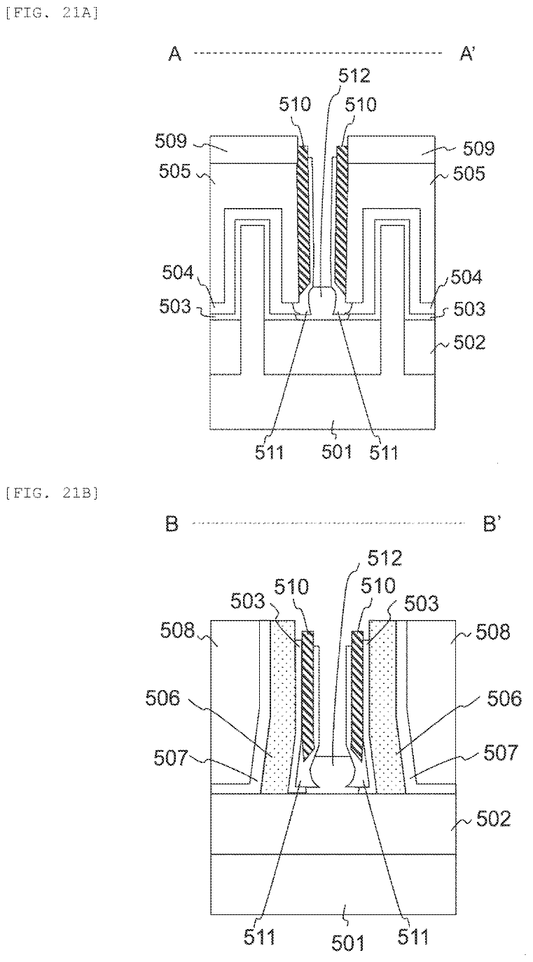

FIG. 17A to FIG. 19A are cross-sectional views of a gate region of a transistor in a direction parallel to a gate (taken along lines A-A′ in FIG. 1 and FIG. 2 of the embodiment 1), illustrating a series of steps of removing a gate insulating film remaining on a gate sidewall spacer in the metal gate cutting process. FIG. 17B to FIG. 19B are cross-sectional views of a gate cut region in a direction perpendicular to the gate (taken along lines B-B′ in FIG. 1 and FIG. 2 of the embodiment 1), illustrating the series of steps of removing the gate insulating film remaining on the gate sidewall spacer in the metal gate cutting process. FIG. 20 shows a flowchart of a series of manufacturing steps in which the metal gate cutting process shown in FIG. 12 of the embodiment 1 to the steps of removing the gate insulating film remaining on the gate sidewall spacer illustrated in FIG. 17A to FIG. 19A and FIG. 17B to FIG. 19B are performed using the same apparatus.

A third protective insulating film 310 is deposited on the structure illustrated in FIG. 11A and FIG. 11B of the embodiment 1 by a film forming technique using the ALD method or the like, thereby obtaining the structure illustrated in FIG. 17A and FIG. 17B. The protective insulating film 310 is deposited on the upper surface and a sidewall of a hard mask 309, the upper surface and a sidewall of a gate insulating film 303, a sidewall of a gate embedding metal 305, a sidewall of a work function metal 304, the upper surface of a gate sidewall spacer 306, the upper surface of an etching stopper layer 307, and the upper surface of an interlayer insulating film 308 of a source-drain region. As a material of the protective insulating film 310, for example, an Si₃N₄ film or an equivalent SiON film, or a SiO₂ film or an Al₂O₃ film may be used. When the protective insulating film 310 is an Si₃N₄ film, for example, BTBAS or BDEAS, or SiH₂Cl₂ is used as a raw material of Si, and an N₂ gas, a mixed gas of an N₂ gas and a hydrogen H₂ gas, or an NH₃ gas is used as a raw material of nitrogen. Similar to the step illustrated in FIG. 5A and FIG. 5B, a gate cut region on which the third protective insulating film 310 is deposited in this step has a narrow and deep pattern with a width of about 10 nm to 30 nm and a depth of about 50 nm to 200 nm. Therefore, at the bottom of the gate cut region, it is assumed that the film thickness of the third protective insulating film 310 in the vertical direction at the bottom is thicker than the film thickness of the third protective insulating film 310 in the horizontal direction on a sidewall of the pattern due to contribution of film formation from the sidewall and a bottom surface. When the film thickness of the third protective insulating film 310 in the horizontal direction at the sidewall of the pattern is, for example, 2 nm to 3 nm, the film thickness of the third protective insulating film 310 in the vertical direction at the bottom of a groove is, for example, 3 nm to 6 nm. A phenomenon in which the film thickness of the third protective insulating film 310 in the vertical direction from the bottom of the gate cut region is thicker than the film thickness of the third protective insulating film 310 in the horizontal direction on the sidewall of the pattern as described above can be intentionally generated by controlling plasma conditions of the ALD method. For example, in the case of forming an Si₃N₄ film as the third protective insulating film 310, only the formation of the Si₃N₄ film in a direction perpendicular to a substrate 301 can be promoted by controlling conditions such as a radio frequency bias applied to the substrate when a gas containing nitrogen is converted into plasma to be reacted on a substrate surface after a precursor of Si is formed on the substrate surface by supplying a raw material of Si to the substrate. As a result, the film thickness of the third protective insulating film 310 in the vertical direction from the bottom of the gate cut region can be made thicker than the film thickness of the third protective insulating film 310 in the horizontal direction at the sidewall of the pattern. In this case, the film thickness of the third protective insulating film 310 at uppermost surfaces of the structure such as the upper surface of the hard mask 309 is also thicker than the film thickness of the third protective insulating film 310 in the horizontal direction at the sidewall of the pattern. When the film thickness of the third protective insulating film 310 in the horizontal direction at the sidewall of the pattern is, for example, 2 nm to 3 nm, the film thickness of the third protective insulating film 310 in the vertical direction at the bottom of the groove can be increased to, for example, 5 nm to 10 nm or more. The present step illustrated in FIG. 17A and FIG. 17B is equivalent to third protective insulating film deposition 409 in the process flowchart of FIG. 20, and may be performed continuously in the same apparatus chamber following a series of steps from a gate metal vertical etching 401 to a first/second protective insulating film isotropic etching 408 (equivalent to 101 to 108 of FIG. 12 of the embodiment 1).

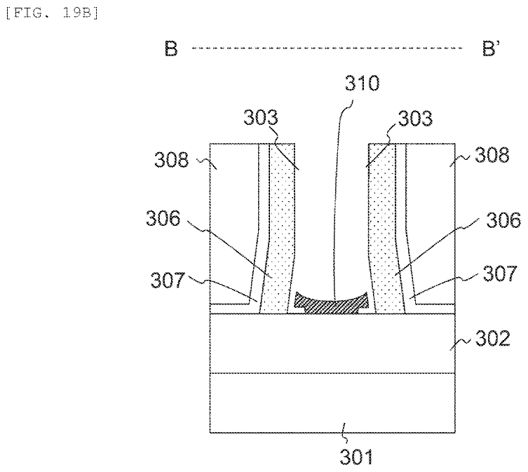

In the step illustrated in FIG. 18A and FIG. 18B, the third protective insulating film 310 is isotropically etched so as to remove the third protective insulating film 310 deposited on a sidewall of the gate cut region. This etching is performed under selective etching conditions with respect to the hard mask 309, the gate insulating film 303, the work function metal 304, the gate embedding metal 305, the gate sidewall spacer 306, the etching stopper layer 307, and the interlayer insulating film 308. For example, when the protective insulating film 310 is an Si₃N₄ film, a gas such as CHF₃, or CH₂F₂, or CH₃F may be used, or a mixed gas of H₂ and a gas such as CF₄ or C₄F₈, or an equivalent gas may be used as an etching gas. This etching is performed under such conditions that the third protective insulating film 310 remains on the bottom surface of the gate cut region after the etching. Further, an etching amount is adjusted such that the upper end of the third protective insulating film 310 remaining after the etching is located at a position higher than a boundary position between the work function metal 304 and the gate insulating film 303 at the sidewall of the gate cut region. For example, when the film thickness of the gate insulating film 303 is 1 nm to 3 nm, an etching time may be adjusted such that the film thickness of the third protective insulating film 310 remaining at the bottom of the gate cut region is about 3 nm to 7 nm. The film formation amount and the etching amount of the third protective insulating film 310 are adjusted so as to satisfy the above-described conditions when an etching time is 1 to 1.5 times the film thickness of the third protective insulating film 310 formed. By this step, the gate insulating film 303 remaining under the work function metal 304 is protected by the third protective insulating film 310. The present step illustrated in FIG. 18A and FIG. 18B is equivalent to third protective insulating film isotropic etching 410 in the process flowchart of FIG. 20, and may be performed continuously in the same apparatus chamber following the third protective insulating film deposition 409 illustrated in FIG. 17A and FIG. 17B.

Here, FIG. 17A and FIG. 17B, and FIG. 18A and FIG. 18B can be considered to correspond to a step of forming a bottom protective insulating film. The step of forming a bottom protective insulating film is a step of forming the third protective insulating film 310 such that only the bottom of the gate cut region is protected by the third protective insulating film 310 by forming the third protective insulating film 310 and isotropically etching the third protective insulating film 310. Since the third protective insulating film 310 is formed so as to protect only the bottom of the gate cut region, the third protective insulating film 310 protecting the bottom of the gate cut region can be also referred to as a bottom protective insulating film. Thus, the carbon film 12 after the etching illustrated in FIG. 13A and FIG. 13B can also be regarded as a bottom protective insulating film, similar to the third protective insulating film 310.

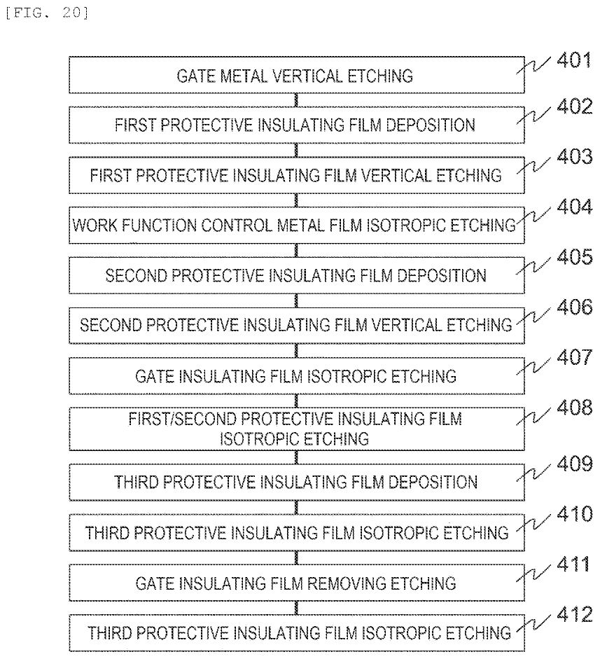

Next, in the step illustrated in FIG. 19A and FIG. 19B, the gate insulating film 303 is isotropically etched so as to remove the gate insulating film 303 remaining on a sidewall of the gate sidewall spacer 306 (FIG. 19B). This etching is performed under selective etching conditions with respect to the third protective insulating film 310, the hard mask 309, the STI insulating film 302, the work function metal 304, the gate embedding metal 305, the gate sidewall spacer 306, the etching stopper layer 307, and the interlayer insulating film 308. In the case of performing dry etching in this etching, for example, when the gate insulating film 303 is HfO₂, a mixed gas of Cl₂, HBr, and O₂, or an equivalent gas is used as an etching gas, for example. An etching amount in this step is adjusted to be 1 to 5 times the film thickness of the gate insulating film 303, and an etching time is controlled such that the gate insulating film 303 on the channel is not removed. The present step illustrated in FIG. 19A and FIG. 19B is equivalent to gate insulating film removing etching 411 in the process flowchart of FIG. 20, and may be performed continuously in the same apparatus chamber following the third protective insulating film isotropic etching 410 illustrated in FIG. 18A and FIG. 18B.

Following the step illustrated in FIG. 19A and FIG. 19B, the third protective insulating film 310 is removed by isotropic etching. This etching is performed under selective etching conditions with respect to the hard mask 309, the gate insulating film 303, the work function metal 304, the gate embedding metal 305, the STI insulating film 302, the gate sidewall spacer 306, the etching stopper layer 307, and the interlayer insulating film 308. For example, when the third protective insulating film 310 is an Si₃N₄ film, a gas such as CHF₃, or CH₂F₂, or CH₃F may be used, or a mixed gas of H₂ and a gas such as CF₄ or C₄F₈, or an equivalent gas may be used as an etching gas. This etching is performed under such conditions that the third protective insulating film 310 is etched for a time 1 to 2 times the etching time required for etching the film thickness, and the third protective insulating film 310 is almost completely removed. The present step is equivalent to third protective insulating film isotropic etching 412 in the process flowchart of FIG. 20, and may be performed continuously in the same apparatus chamber following the gate insulating film removing etching 411 illustrated in FIG. 19A and FIG. 19B. By this step, a structure equivalent to the structure illustrated in FIG. 15A and FIG. 15B of the embodiment 1 is obtained.

In the present embodiment, the gate metal vertical etching 401 to the third protective insulating film isotropic etching 412 of the process flowchart shown in FIG. 20 can be performed in the same apparatus chamber as continuous steps. That is, the metal gate cutting process shown in the flowchart of FIG. 12 of the embodiment 1 to the subsequent step of removing the gate insulating film 303 remaining on the sidewall of the gate sidewall spacer 306 can be performed in the same apparatus as a series of continuous steps without taking out the substrate from the apparatus.

### Embodiment 3

An embodiment 3 provides a technique in which, in the metal gate cutting process of the embodiment 1, the sidewalls of the work function metal 4 and the gate embedding metal 5 in the gate cut region are protected in the step of removing the gate insulating film 3 remaining on the sidewall of the gate sidewall spacer 6 illustrated in FIG. 13A and FIG. 13B to FIG. 15A and FIG. 15B.

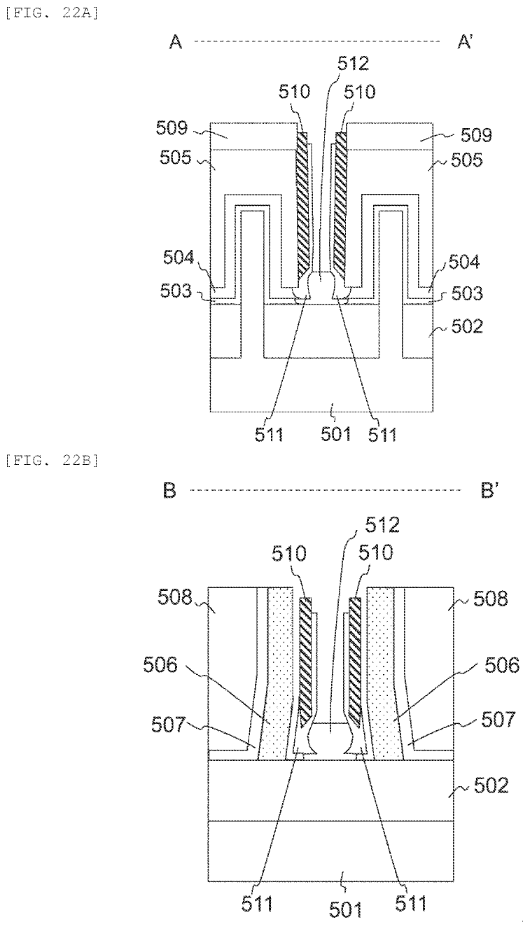

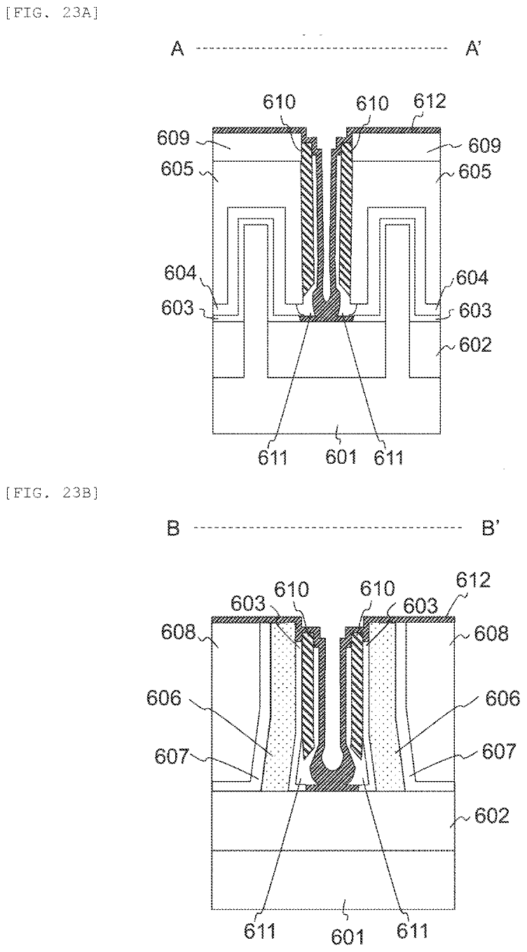

FIG. 21A to FIG. 22A are cross-sectional views of a gate region of a transistor in a direction parallel to a gate (taken along lines A-A′ in FIG. 1 and FIG of the embodiment 1), illustrating a series of steps of removing a gate insulating film remaining on a gate sidewall spacer in the metal gate cutting process. FIG. 21B to FIG. 22B are cross-sectional views of a gate cut region in a direction perpendicular to the gate (taken along lines B-B′ in FIG. 1 and FIG. 2 of the embodiment 1), illustrating the series of steps of removing the gate insulating film remaining on the gate sidewall spacer in the metal gate cutting process.

On the structure illustrated in FIG. 10A and FIG. 10B of the embodiment 1, a groove formed by the gate cut region is filled with a coating film such as a spin-on carbon film, and then the carbon film is etched in the vertical direction to a certain amount, thereby obtaining the structure illustrated in FIG. 21A and FIG. 21B. Here, the etching amount of a carbon film 512 is adjusted such that the upper end of the carbon film 512 after the etching is located at a position higher than a boundary position between a work function metal 504 and a gate insulating film 503 at the sidewall of the gate cut region, and is located at a position at which a second protective insulating film 511 is exposed. For example, the height of the carbon film 512 remaining on an STI insulating film 502 after the etching may be adjusted to about 3 nm to 20 nm. By this step, the gate insulating film 503 remaining under the work function metal 504 is protected by the carbon film 512.

In the step illustrated in FIG. 22A and FIG. 22B, the gate insulating film 503 is etched so as to remove the gate insulating film 503 remaining on a sidewall of the gate sidewall spacer 506 (FIG. 22B). The etching is performed under selective etching conditions with respect to the carbon film 512, the second protective insulating film 511, a first protective insulating film 510, a hard mask 509, an STI insulating film 502, the gate sidewall spacer 506, an etching stopper layer 507, and an interlayer insulating film 508. In order to avoid excessive etching of the gate insulating film 503 in the horizontal direction, this etching is mainly performed under vertical etching conditions using dry etching, and only residues that cannot be removed by the vertical etching are removed by isotropic etching. For example, when the gate insulating film 503 is HfO₂, a mixed gas of Cl₂, HBr, and O₂, or an equivalent gas is used for the vertical etching and the isotropic etching. In order to further increase etching selectivity with respect to other materials, a method of repeating a cycle of selectively depositing a carbon-based material on materials other than the gate insulating film 503 and etching the gate insulating film 503 while protecting these materials may be used for this etching. In that case, a gas such as CH₄ or CHF₃ may be used for the above-described process of depositing the carbon-based material. In this step, the etching amount of the gate insulating film 503 by the isotropic etching is adjusted to be 1 to 5 times the film thickness of the gate insulating film 503, and an etching time and a balance with a vertical etching time are controlled such that the gate insulating film 503 on the channel is not removed.

Next, the carbon film 512 is removed, for example, by performing ashing in an oxygen-plasma atmosphere, and further, the second protective insulating film 511 and the first protective insulating film 510 are sequentially removed by using isotropic etching, thereby obtaining a structure equivalent to the structure illustrated in FIG. 15A and FIG. 15B of the embodiment 1.

The step of vertically etching the carbon film 512 illustrated in FIG. 21A and FIG. 21B to the step of sequentially removing the second protective insulating film 511 and the first protective insulating film 510 may be continuously performed in the same apparatus chamber. The apparatus used at this time may be the same as the apparatus in which gate metal vertical etching (equivalent to step 101 in FIG. 12 of the embodiment 1) to gate insulating film isotropic etching (equivalent to step 107 in FIG. 12 of the embodiment 1) are performed.

In the present embodiment, in performing etching to remove the gate insulating film 503 remaining on the gate sidewall spacer 506 in the gate cut region, since a sidewall of the work function metal 504 and a sidewall of the gate embedding metal 505 are covered with the second protective insulating film 511 and the first protective insulating film 510, these metals (504 and 505) can be prevented from being etched.

### Embodiment 4

An embodiment 4 provides a technique in which, in the metal gate cutting process of the embodiment 3, the series of steps of cutting the metal gate (equivalent to the series of steps 101 to 107 in FIG. 12 of the embodiment 1) to the step of removing the gate insulating film 503 remaining on the gate sidewall spacer 506 (FIG. 22A and FIG. 22B of the embodiment 3), and further to the step of removing the second protective insulating film 511 and the first protective insulating film 510 are continuously performed in the same apparatus chamber.

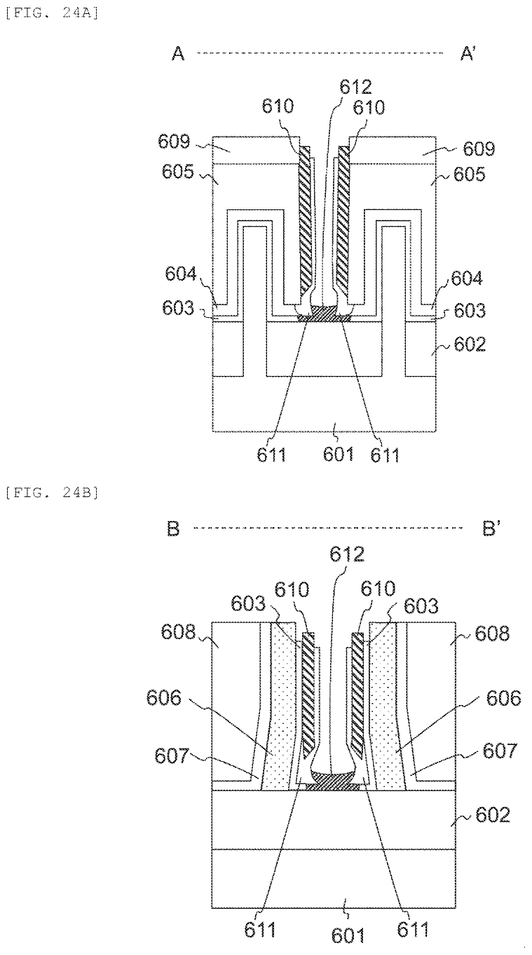

FIG. 23A to FIG. 25A are cross-sectional views of a gate region of a transistor in a direction parallel to a gate (taken along lines A-A′ in FIG. 1 and FIG. 2 of the embodiment 1), illustrating a series of steps of removing a gate insulating film remaining on a gate sidewall spacer in the metal gate cutting process. FIG. 23B to FIG. 25B are cross-sectional views of a gate cut region in a direction perpendicular to the gate (taken along lines B-B′ in FIG. 1 and FIG. 2 of the embodiment 1), illustrating the series of steps of removing the gate insulating film remaining on the gate sidewall spacer in the metal gate cutting process. FIG. 26 shows a flowchart of a series of manufacturing steps in which the series of steps of cutting the metal gate (equivalent to the series of steps 101 to 107 in FIG. 12 of the embodiment 1) to the steps of removing the gate insulating film remaining on the gate sidewall spacer and further removing the second protective insulating film and the first protective insulating film are performed using the same apparatus.

A third protective insulating film 612 is deposited on the structure illustrated in FIG. 10A and FIG. 10B of the embodiment 1 by a film forming technique using the ALD method or the like, thereby obtaining the structure illustrated in FIG. 23A and FIG. 23B. The protective insulating film 612 is deposited on the upper surface and a sidewall of a hard mask 609, a sidewall and the upper surface of a first protective insulating film 610, a sidewall and the upper surface of a second protective insulating film 611, the upper surface and a sidewall of a gate insulating film 603, the upper surface of a gate sidewall spacer 606, the upper surface of an etching stopper layer 607, and the upper surface of an interlayer insulating film 608 of a source-drain region. As a material of the protective insulating film 612, for example, an Si₃N₄ film or an equivalent SiON film, or an SiO₂ film or an Al₂O₃ film may be used. When the protective insulating film 612 is an Si₃N₄ film, for example, BTBAS or BDEAS, or SiH₂Cl₂ is used as a raw material of Si, and an N₂ gas, a mixed gas of an N₂ gas and a hydrogen H₂ gas, or a NH₃ gas is used as a raw material of nitrogen. The gate cut region at which the third protective insulating film 612 is deposited in this step has a depth of about 50 nm to 200 nm and a width that is expected to be even narrower (a width of about 5 nm to 20 nm) than in the case of FIG. 17A and FIG. 17B (a width of about 10 nm to 30 nm). At the bottom of the gate cut region having a pattern with a narrow width and a depth as described above, it is assumed that the film thickness of the third protective insulating film 612 in the vertical direction at the bottom is thicker than the film thickness in the horizontal direction on a sidewall of the pattern due to contribution of film formation from the sidewall and a bottom surface. When the film thickness of the third protective insulating film 612 in the horizontal direction at the sidewall of the pattern is, for example, 2 nm to 3 nm, the film thickness in the vertical direction at the bottom of a groove is, for example, 3 nm to 6 nm. Similar to the embodiment 2, a phenomenon in which the film thickness of the third protective insulating film 612 in the vertical direction from the bottom of the gate cut region is thicker than the film thickness of the third protective insulating film 612 in the horizontal direction on the sidewall of the pattern as described above can be intentionally generated by controlling plasma conditions of the ALD method. By using the method described in the embodiment 2, when the film thickness of the third protective insulating film 612 in the horizontal direction at the sidewall of the pattern is, for example, 2 nm to 3 nm, the film thickness of the third protective insulating film 612 in the vertical direction at the bottom of the groove can be increased to, for example, 5 nm to 10 nm or more. The present step illustrated in FIG. 23A and FIG. 23B is equivalent to third protective insulating film deposition 708 in the process flowchart of FIG. 26, and may be performed continuously in the same apparatus chamber following a series of steps from a gate metal vertical etching 701 to a gate insulating film isotropic etching 707 (equivalent to the continuous steps 101 to 107 in FIG. 12 of the embodiment 1).

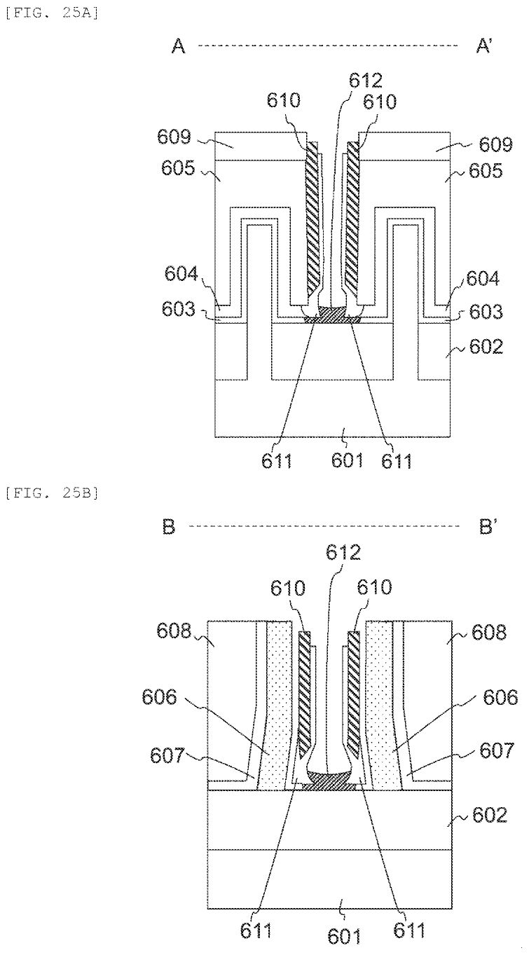

In the step illustrated in FIG. 24A and FIG. 24B, the third protective insulating film 612 is isotropically etched so as to remove the third protective insulating film 612 deposited on a sidewall of the gate cut region. The etching is performed under selective etching conditions with respect to the hard mask 609, the first protective insulating film 610, the second protective insulating film 611, the gate sidewall spacer 606, the etching stopper layer 607, and the interlayer insulating film 608. For example, when the protective insulating film 612 is an Si₃N₄ film, a gas such as CHF₃, or CH₂F₂, or CH₃F may be used, or a mixed gas of H₂ and a gas such as CF₄ or C₄F₈, or an equivalent gas may be used as an etching gas. This etching is performed under such conditions that the third protective insulating film 612 remains on the bottom surface of the gate cut region after the etching. Further, an etching amount is adjusted such that the upper end of the third protective insulating film 612 remaining after the etching is located at a position higher than a boundary position between the work function metal 604 and the gate insulating film 603 at the sidewall of the gate cut region. For example, when the film thickness of the gate insulating film 603 is 1 nm to 3 nm, an etching time may be adjusted such that the film thickness of the third protective insulating film 612 remaining at the bottom of the gate cut region is about 3 nm to 7 nm. The film formation amount and the etching amount of the third protective insulating film 612 is adjusted so as to satisfy the above-described conditions when the etching time is 1 to 1.5 times the film thickness of the third protective insulating film 612 formed. By this step, the gate insulating film 603 remaining under the work function metal 604 is protected by the third protective insulating film 612. The present step illustrated in FIG. 24A and FIG. 24B is equivalent to third protective insulating film isotropic etching 709 in the process flowchart of FIG. 26, and may be performed continuously in the same apparatus chamber following the third protective insulating film deposition 708 illustrated in FIG. 23A and FIG. 23B. Similar to the third protective insulating film 310, the third protective insulating film 612 can also be regarded as a bottom protective insulating film.

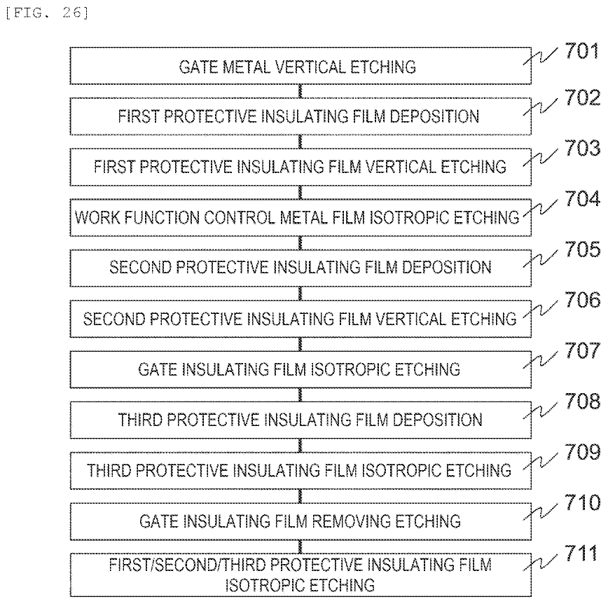

Next, in the step illustrated in FIG. 25A and FIG. 25B, the gate insulating film 603 is etched so as to remove the gate insulating film 603 remaining on a sidewall of the gate sidewall spacer 606 (FIG. 25B). The etching is performed under selective etching conditions with respect to the third protective insulating film 612, the second protective insulating film 611, the first protective insulating film 610, the hard mask 609, an STI insulating film 602, the gate sidewall spacer 606, the etching stopper layer 607, and the interlayer insulating film 608. In order to avoid excessive etching of the gate insulating film 603 in the horizontal direction, this etching is mainly performed under vertical etching conditions using dry etching, and only residues that cannot be removed by the vertical etching are removed by isotropic etching. For example, when the gate insulating film 603 is HfO₂, a mixed gas of Cl₂, HBr, and O₂, or an equivalent gas is used for the vertical etching and the isotropic etching. In order to further increase etching selectivity with respect to other materials, a method of repeating a cycle of selectively depositing a carbon-based material on materials other than the gate insulating film 603 and etching the gate insulating film 603 while protecting these materials may be used for this etching. In that case, a gas such as CH₄ or CHF₃ may be used for the above-described process of depositing the carbon-based material. In this step, the etching amount of the gate insulating film 603 by the isotropic etching is adjusted to be 1 to 5 times the film thickness of the gate insulating film 603, and an etching time and a balance with a vertical etching time are controlled such that the gate insulating film 603 on the channel is not removed. The present step illustrated in FIG. 25A and FIG. 25B is equivalent to gate insulating film removing etching 710 in the process flowchart of FIG. 26, and may be performed continuously in the same apparatus chamber following the third protective insulating film isotropic etching 709 illustrated in FIG. 24A and FIG. 24B.

Next, the third protective insulating film 612, the second protective insulating film 611, and the first protective insulating film 610 are sequentially removed by using isotropic etching, thereby obtaining a structure equivalent to the structure illustrated in FIG. 15A and FIG. 15B of the embodiment 1. A method of removing each film by etching is the same as in the embodiments 1 to 3. The present step is equivalent to first/second/third protective insulating film isotropic etching 711 in the process flowchart of FIG. 26, and may be performed continuously in the same apparatus chamber following the gate insulating film removing etching 710 illustrated in FIG. 25A and FIG. 25B.

In the present embodiment, the gate metal vertical etching 701 to the first/second/third protective insulating film isotropic etching 711 of the flowchart shown in FIG. 26 can be performed in the same apparatus chamber as continuous steps. In other word, the steps of the embodiment 3, that is, the series of steps of cutting the metal gate (equivalent to the series of steps 101 to 107 in FIG. 12 of the embodiment 1) to the step of removing the gate insulating film 503 remaining on the gate sidewall spacer 506 (FIG. 22A and FIG. 22B of the embodiment 3), and further to the step of removing the second protective insulating film 511 and the first protective insulating film 510 can be performed in the same apparatus as a series of continuous steps without taking out the substrate from the apparatus.

### REFERENCE SIGNS LIST

1, 301, 501, 601: Semiconductor substrate
2, 302, 502, 602: Shallow trench isolation (STI) insulating film
3, 303, 503, 603: high dielectric constant (high-k) gate insulating film
4, 304, 504, 604: Work function metal
5, 305, 505, 605: Gate embedding metal
6, 306, 506, 606: Gate sidewall spacer
7, 307, 507, 607: Etching stopper layer
8, 308, 508, 608: Interlayer insulating film of source-drain region
9, 309, 509, 609: Hard Mask
10, 510, 610: First protective insulating film
11, 511, 611: Second protective insulating film
12, 512: Carbon film
310, 612: Third protective insulating film
101, 401, 701: Gate metal vertical etching step
102, 402, 702: First protective insulating film deposition step
103, 403, 703: First protective insulating film vertical etching step
104, 404, 704: Work function control metal film isotropic etching step
105, 405, 705: Second protective insulating film deposition step
106, 406, 706: Second protective insulating film vertical etching step
107, 407, 707: Gate insulating film isotropic etching step
108, 408: First/Second protective insulating film isotropic etching step
409, 708: Third protective insulating film deposition step
410, 709: Third protective insulating film isotropic etching step
411, 710: Gate insulating film removing etching step
412: Third Protective Insulating Film Isotropic etching step
710: First/Second/Third protective insulating film isotropic etching step
201: Processing chamber
201A: Upper portion of processing chamber
201B: Lower portion of processing chamber
202: Vacuum exhaust port
203: Window portion
204: Porous plate
205: Gas source
206: Gas supply apparatus
207: Gas introduction port
208: Plasma generation radio frequency power source
209: Waveguide
210: Magnetic field generation coil
211: Semiconductor substrate
212: Specimen table
213: High-frequency bias power supply
220: Control unit
221: Control signal
t1: Film thickness of first protective insulating film in horizontal direction on sidewall of metal gate cut cross section
t1′: Film thickness of first protective insulating film in horizontal direction on sidewall of gate sidewall spacer
t2, t2′: Film thickness of first protective insulating film at bottom of gate cut region
t3: Film thickness of second protective insulating film in horizontal direction on sidewall of metal gate cut cross section
t3′: Film thickness of second protective insulating film in horizontal direction on sidewall of gate sidewall spacer
t4: Film thickness of second protective insulating film in horizontal direction on sidewall of metal gate cut cross section under eaves formed by first protective insulating film at bottom of gate cut region
t4′: Film thickness of second protective insulating film in horizontal direction on sidewall of gate sidewall spacer under eaves formed by first protective insulating film at bottom of gate cut region
t5, t5′: Film thickness of second protective insulating film in vertical direction at bottom of gate cut region
θ1: Angle formed by sidewall of metal gate cut cross section and lower surface of first protective insulating film after etching
θ1′: Angle formed by sidewall of gate sidewall spacer and lower surface of first protective insulating film after etching
a1: Ion irradiation path during second protective insulating film etching

1-17. (canceled)

18. A method for manufacturing a semiconductor device in which gate structures are isolated and separated from each other by an insulating film by vertically cutting a gate film stack,
the semiconductor device having a channel including a fin-like shape, wire-like shape, or sheet-like shape and the gate film stack being staked with a gate insulating film and a metal layer and being on the channel,
the method comprising:
a first step of forming a cut region by etching the metal layer in a vertical direction;
the second step of depositing a first protective insulating film on a sidewall of the cut region;
a third step of exposing the gate insulating film in the cut region by anisotropic etching of the first protective insulating film;
a fourth step of removing a part of the metal layer by isotropic etching;
a fifth step of depositing a second protective insulating film different from the first protective insulating film on the sidewall of the cut region;
a sixth step of exposing the gate insulating film in the cut region by anisotropic etching the second protective insulating film; and
a seventh step of removing a part of the exposed gate insulating film in the cut region,
wherein the gate structures are formed from the gate file stack and are oriented perpendicular to an orientation direction of the channel, and
wherein a gate sidewall spacer is formed on the sidewall of the gate structure.

19. The method for manufacturing a semiconductor device according to claim 18,
wherein
the first step to the seventh step are performed consecutively in the same plasma processing apparatus.

20. The method for manufacturing a semiconductor device according to claim 18, wherein
the first protective insulating film comprises a silicon nitride film, and
the second protective insulating film comprises an aluminum oxide film.

21. The method for manufacturing a semiconductor device according to claim 18,
wherein
a sidewall of the gate film stack exposed by the third step is covered by the fifth step.

22. The method for manufacturing a semiconductor device according to claim 18, further comprising:
after the seventh step, an eighth step of removing the first protective insulating film and the second protective insulating film by isotropic etching.

23. The method for manufacturing a semiconductor device according to claim 22, further comprising:
after the eighth step, a ninth step of removing the gate insulating film on a sidewall of the gate sidewall spacer by isotropic etching.

24. The method for manufacturing a semiconductor device according to claim 22, further comprising:
after the eighth step, a ninth step of applying an organic film;
a tenth step of etching the applied organic film in a direction perpendicular to a semiconductor substrate, and controlling the amount of etching so that the gate insulating film on the sidewall of the gate sidewall spacer is exposed and a top surface of the etched organic film is higher than the height of the gate insulating film at a bottom of the metal layer;
an eleventh step of removing the gate insulating film on a sidewall of the gate sidewall spacer by isotropic etching; and
a twelfth step of removing the organic film.

25. The method for manufacturing a semiconductor device according to claim 22, further comprising:
after the eighth step, a ninth step of forming a bottom protective insulating film to protect a bottom of the cut region by isotropic etching a deposited insulating film;
a tenth step of removing the gate insulating film on the sidewall of the gate sidewall spacer by isotropic etching; and
an eleventh step of removing the bottom protective insulating film by isotropic etching.

26. The method for manufacturing a semiconductor device according to claim 18, further comprising:
after the seventh step, an eighth step of applying an organic film;
a ninth step of etching the applied organic film in a direction perpendicular to a semiconductor substrate, and controlling the amount of etching so that a part of a stacked film in which the first protective insulating film and the second protective insulating film are stacked is exposed and a top surface of the organic film is higher than the height of the gate insulating film at a bottom of the metal layer;
a tenth step of removing the gate insulating film of the sidewall of the gate sidewall spacer by anisotropic etching and isotropic etching;
an eleventh step of removing the organic film; and
a twelfth step of removing the stacked film by isotropic etching.

27. The method for manufacturing a semiconductor device according to claim 18, further comprising:
after the seventh step, an eighth step of forming a bottom protective insulating film to protect a bottom of the cut region by isotropic etching a deposited insulating film;
a ninth step of removing the gate insulating film on the sidewall of the gate sidewall spacer by anisotropic etching and isotropic etching;
a tenth step of removing the bottom protective insulating film by isotropic etching; and
an eleventh step of removing a stacked film in which the first protective insulating film and the second protective insulating film are stacked by isotropic etching.

28. A method for performing plasma processing on a semiconductor device in which gate structures are isolated and separated from each other by an insulating film by vertically cutting a gate film stack,
the semiconductor device having a channel including a fin-like shape, wire-like shape, or sheet-like shape and the gate film stack being stacked with a gate insulating film and a metal layer and being on the channel,
the method comprising:
a first step of forming a cut region by etching the metal layer in a vertical direction;
a second step of depositing a first protective insulating film on a sidewall of the cut region;
a third step of exposing the gate insulating film in the cut region by anisotropic etching of the first protective insulating film;
a fourth step of removing a part of the metal layer by isotropic etching;
a fifth step of depositing a second protective insulating film different from the first protective insulating film on the sidewall of the cut region;
a sixth step of exposing the gate insulating film in the cut region by anisotropic etching the second protective insulating film; and
a seventh step of removing a part of the exposed gate insulating film in the cut region,
wherein the gate structures are formed from the gate file stack and are oriented perpendicular to an orientation direction of the channel, and
wherein a gate sidewall spacer is formed on the sidewall of the gate structure.

29. The method for performing plasma processing on a semiconductor device according to claim 28, further comprising:
an eighth step of removing a stacked film in which the first protective insulating film and the second protective insulating film are stacked by isotropic etching,
wherein the first step to the eighth step are performed consecutively in the same plasma processing apparatus.

30. The method for performing plasma processing on a semiconductor device according to claim 29, further comprising:
a ninth step of removing the gate insulating film on the sidewall of the gate sidewall spacer by isotropic etching.

31. The method for performing plasma processing on a semiconductor device according to claim 29, further comprising:
a ninth step of forming a bottom protective insulating film to protect a bottom of the cut region by isotropic etching a deposited insulating film;
a tenth step of removing the gate insulating film on the sidewall of the gate sidewall spacer by isotropic etching; and
an eleventh step is to remove the bottom protective insulating film by isotropic etching.

32. A method for performing plasma processing on a semiconductor device according to claim 28, further comprising:
an eighth step of forming a bottom protective insulating film to protect a bottom of the cut region by isotropic etching a deposited insulating film;
a ninth step of removing the gate insulating film on the sidewall of the gate sidewall spacer by anisotropic etching;
a tenth step of removing the bottom protective insulating film by isotropic etching; and
an eleventh step of removing a stacked film in which the first protective insulating film and the second protective insulating film are stacked by isotropic etching.

33. A method for performing plasma processing on a semiconductor device according to claim 31, wherein
the first protective insulating film and the second protective insulating film are deposited by an ALD method.

34. A method for performing plasma processing on a semiconductor device according to claim 32, wherein
the first protective insulating film and the second protective insulating film are deposited by an ALD method.
